(19) United States
(12) Patent Application Publication
(10) Pub. No.: US 2024/0130137 A1
(43) Pub. Date: Apr. 18, 2024

(54) THREE-DIMENSIONAL MEMORY DEVICE CONTAINING SELF-ALIGNED FERROELECTRIC MEMORY ELEMENTS AND METHOD OF MAKING THE SAME

(71) Applicant: SANDISK TECHNOLOGIES LLC, Addison, TX (US)

(72) Inventors: Kartik Sondhi, Milpitas, CA (US); Raghuveer S. Makala, Campbell, CA (US); Adarsh Rajashekhar, Santa Clara, CA (US); Rahul Sharangpani, Fremont, CA (US); Fei Zhou, San Jose, CA (US)

(21) Appl. No.: 18/233,628

(22) Filed: Aug. 14, 2023

Related U.S. Application Data
(60) Provisional application No. 63/379,475, filed on Oct. 14, 2022.

(51) Int. Cl. H10B 51/20; H10B 51/10; H10B 51/40

(52) U.S. Cl. CPC H10B 51/20; H10B 51/10; H10B 51/40

(57) ABSTRACT

A semiconductor memory device includes an alternating stack of insulating layers and electrically conductive layers, a memory opening vertically extending through the alternating stack, and a memory opening fill structure located in the memory opening and including a vertical semiconductor channel and a vertical stack of discrete ferroelectric material portions located at levels of the electrically conductive layers. The discrete ferroelectric material portions protrude inward into the memory opening relative to vertical sidewalls of the insulating layers.

### FIELD

The present disclosure relates generally to the field of semiconductor devices, and particularly to three-dimensional memory devices containing self-aligned ferroelectric memory elements and methods of manufacturing the same.

### BACKGROUND

A ferroelectric material refers to a material that displays spontaneous polarization of electrical charges in the absence of an applied electric field. The net polarization P of electrical charges within the ferroelectric material is non-zero in the minimum energy state. Thus, spontaneous ferroelectric polarization of the material occurs, and the ferroelectric material accumulates surfaces charges of opposite polarity types on two opposing surfaces. Polarization P of a ferroelectric material as a function of an applied voltage V thereacross displays hysteresis. The product of the remanent polarization and the coercive field of a ferroelectric material is a metric for characterizing effectiveness of the ferroelectric material.

A ferroelectric memory device is a memory device containing the ferroelectric material which is used to store information. The ferroelectric material acts as the memory material of the memory device. The dipole moment of the ferroelectric material is programmed in two different orientations (e.g., “up” or “down” polarization positions based on atom positions, such as oxygen and/or metal atom positions, in the crystal lattice) depending on the polarity of the applied electric field to the ferroelectric material to store information in the ferroelectric material. The different orientations of the dipole moment of the ferroelectric material may be detected by the electric field generated by the dipole moment of the ferroelectric material. For example, the orientation of the dipole moment may be detected by measuring electrical current passing through a semiconductor channel provided adjacent to the ferroelectric material in a field effect transistor ferroelectric memory device.

### SUMMARY

According to an aspect of the present disclosure, a semiconductor memory device comprises an alternating stack of insulating layers and electrically conductive layers; a memory opening vertically extending through the alternating stack; and a memory opening fill structure located in the memory opening and comprising a vertical semiconductor channel and a vertical stack of discrete ferroelectric material portions located at levels of the electrically conductive layers, wherein the discrete ferroelectric material portions protrude inward into the memory opening relative to vertical sidewalls of the insulating layers.

According to another aspect of the present disclosure, a method of forming a semiconductor memory device is provided. The method comprises: forming a combination of an alternating stack of insulating layers and electrically conductive layers having an opening therethrough and a vertical stack of tubular dielectric material portions located at a periphery of the opening at a level of a respective one of the insulating layers, wherein the vertical stack of tubular dielectric material portions comprises physically exposed hydrophobic surfaces; forming a vertical stack of discrete ferroelectric material portions by performing a selective deposition process in which a ferroelectric material selectively grows from physically exposed surfaces of the electrically conductive layers while growth of the ferroelectric material from the physically exposed hydrophobic surfaces is suppressed; and forming a vertical semiconductor channel over the vertical stack of discrete ferroelectric material portions.

### BRIEF DESCRIPTION OF THE DRAWINGS

FIG. 1 is a schematic vertical cross-sectional view of a first exemplary structure after formation of at least one peripheral device and a semiconductor material layer according to a first embodiment of the present disclosure.

FIG. 2 is a schematic vertical cross-sectional view of the first exemplary structure after formation of an alternating stack of insulating layers and sacrificial material layers according to the first embodiment of the present disclosure.

FIG. 3 is a schematic vertical cross-sectional view of the first exemplary structure after formation of stepped terraces and a retro-stepped dielectric material portion according to the first embodiment of the present disclosure.

FIG. 4A is a schematic vertical cross-sectional view of the first exemplary structure after formation of memory openings and support openings according to the first embodiment of the present disclosure.

FIG. 4B is a top-down view of the first exemplary structure of FIG. 4A. The vertical plane A-A′ is the plane of the cross-section for FIG. 4A.

FIG. 5 is a schematic vertical cross-sectional view of the first exemplary structure after formation of sacrificial memory opening fill structures and sacrificial support pillar structures according to the first embodiment of the present disclosure.

FIG. 6A is a schematic vertical cross-sectional view of the first exemplary structure after formation of a sacrificial cover layer and backside trenches according to the first embodiment of the present disclosure.

FIG. 6B is a partial see-through top-down view of the first exemplary structure of FIG. 6A. The vertical plane A-A′ is the plane of the schematic vertical cross-sectional view of FIG. 6A.

FIG. 7 is a schematic vertical cross-sectional view of the first exemplary structure after formation of backside recesses according to the first embodiment of the present disclosure.

FIG. 8 is a schematic vertical cross-sectional view of the first exemplary structure after dividing each dielectric material liner into a vertical stack of tubular dielectric material portions according to the first embodiment of the present disclosure.

FIG. 9 is a schematic vertical cross-sectional view of the first exemplary structure after formation of electrically conductive layers in the backside trenches according to the first embodiment of the present disclosure.

FIG. 10A is a schematic vertical cross-sectional view of the first exemplary structure after formation of backside trench fill structures according to the first embodiment of the present disclosure.

FIG. 10B is a partial see-through top-down view of the first exemplary structure of FIG. 10A. The vertical plane A-A′ is the plane of the schematic vertical cross-sectional view of FIG. 10A.

FIG. 11 is a schematic vertical cross-sectional view of the first exemplary structure after removal of sacrificial opening fill material portions according to the first embodiment of the present disclosure.

FIG. 12A is a schematic vertical cross-sectional view of the first exemplary structure after formation of vertical stacks of discrete ferroelectric material portions and vertical stacks of discrete dielectric metal oxide portions according to the first embodiment of the present disclosure.

FIG. 12B is a magnified view of a region of the first exemplary structure of FIG. 12A around a discrete ferroelectric material portion.

FIG. 13 is a schematic vertical cross-sectional view of the first exemplary structure after formation of a semiconductor channel material layer according to the first embodiment of the present disclosure.

FIG. 14A is a schematic vertical cross-sectional view of the first exemplary structure after formation of memory opening fill structures and support pillar structures according to the first embodiment of the present disclosure.

FIG. 14B is a top-down view of the first exemplary structure of FIG. 14A. The vertical plane A-A′ is the plane of the schematic vertical cross-sectional view of FIG. 14A.

FIG. 15A is a schematic vertical cross-sectional view of the first exemplary structure after formation of a contact-level dielectric layer and various contact via structures according to the first embodiment of the present disclosure.

FIG. 15B is a top-down view of the first exemplary structure of FIG. 15A. The vertical plane A-A′ is the plane of the schematic vertical cross-sectional view of FIG. 15A.

FIG. 16A is a vertical cross-sectional view of a second exemplary structure after removing a predominant portion of each of the tubular dielectric material portions according to a second embodiment of the present disclosure.

FIG. 16B is a magnified view of a region of the second exemplary structure of FIG. 16A around a discrete ferroelectric material portion.

FIG. 17 is a schematic vertical cross-sectional view of the second exemplary structure after formation of a semiconductor channel material layer according to the second embodiment of the present disclosure.

FIG. 18 is a schematic vertical cross-sectional view of the second exemplary structure after formation of memory opening fill structures and support pillar structures according to the second embodiment of the present disclosure.

FIG. 19 is a schematic vertical cross-sectional view of the second exemplary structure after formation of a contact-level dielectric layer and various contact via structures according to the second embodiment of the present disclosure.

FIG. 20 is a schematic vertical cross-sectional view of a third exemplary structure after formation of an alternating stack of insulating layers and electrically conductive layers according to a third embodiment of the present disclosure.

FIG. 21 is a schematic vertical cross-sectional view of the third exemplary structure after formation of stepped surfaces and a retro-stepped dielectric material portion according to the third embodiment of the present disclosure.

FIG. 22A is a schematic vertical cross-sectional view of the third exemplary structure after formation of memory openings and support openings according to the third embodiment of the present disclosure.

FIG. 22B is a top-down view of the first exemplary structure of FIG. 22A. The vertical plane A-A′ is the plane of the cross-section for FIG. 22A.

FIGS. 23A-23G are sequential vertical cross-sectional views of a region of a memory opening during formation of a memory opening fill structure according to the third embodiment of the present disclosure.

FIG. 24A is a schematic vertical cross-sectional view of the third exemplary structure after formation of backside trenches according to the third embodiment of the present disclosure.

FIG. 24B is a top-down view of the first exemplary structure of FIG. 24A. The vertical plane A-A′ is the plane of the cross-section for FIG. 24A.

FIG. 24C is a magnified view of a region of the third exemplary structure of FIGS. 24A and 24B around a discrete ferroelectric material portion.

FIG. 25A is a schematic vertical cross-sectional view of the third exemplary structure after formation of backside trench fill structures according to the third embodiment of the present disclosure.

FIG. 25B is a top-down view of the first exemplary structure of FIG. 25A. The vertical plane A-A′ is the plane of the cross-section for FIG. 25A.

FIG. 26A is a schematic vertical cross-sectional view of the third exemplary structure after formation of contact via structures according to the third embodiment of the present disclosure.

FIG. 26B is a top-down view of the first exemplary structure of FIG. 26A. The vertical plane A-A′ is the plane of the cross-section for FIG. 26A.

### DETAILED DESCRIPTION

As discussed above, the embodiments of the present disclosure are directed to three-dimensional memory devices containing self-aligned ferroelectric memory elements and methods of manufacturing the same, the various aspects of which are described below. The embodiments of the disclosure may be employed to form various structures including a multilevel memory structure, non-limiting examples of which include semiconductor devices such as three-dimensional memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. As used herein, a first element located “on” a second element may be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded thereamongst, for example, by flip-chip bonding or another chip-to-chip bonding. A package or a chip may include a single semiconductor die (or a “die”) or a plurality of semiconductor dies. A die is the smallest unit that can independently execute external commands or report status. Typically, a package or a chip with multiple dies is capable of simultaneously executing as many number of external commands as the total number of planes therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

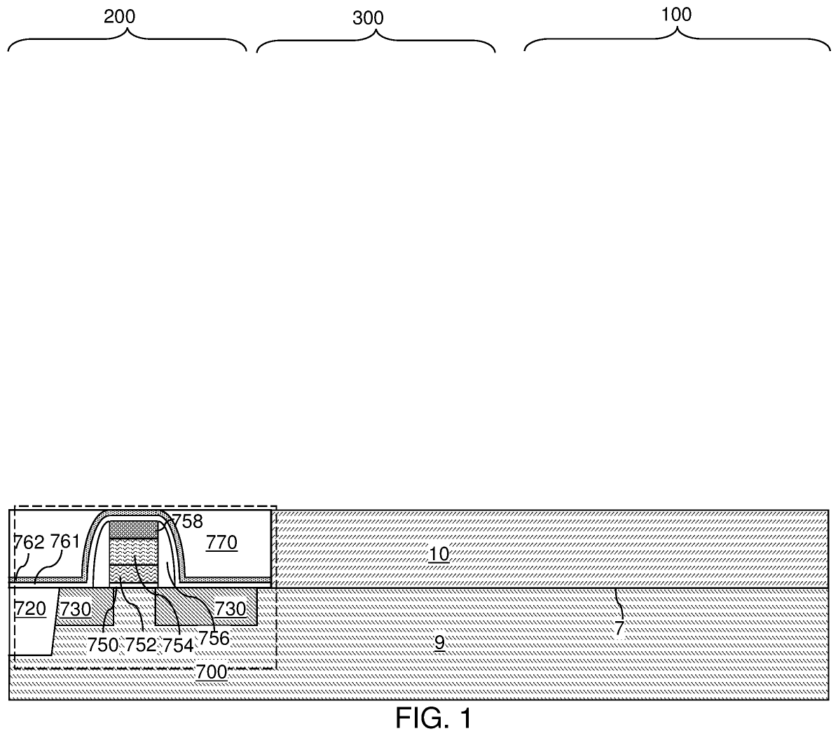

Referring to FIG. 1, a first exemplary structure according to the first embodiment of the present disclosure is illustrated, which may be employed, for example, to fabricate a device structure containing vertical NAND memory devices. The first exemplary structure includes a substrate (9, 10), which may be a semiconductor substrate. The substrate can include a substrate semiconductor layer 9 and an optional semiconductor material layer 10. The substrate semiconductor layer 9 maybe a semiconductor wafer or a semiconductor material layer, and can include at least one elemental semiconductor material (e.g., single crystal silicon wafer or layer), at least one III-V compound semiconductor material, at least one II-VI compound semiconductor material, at least one organic semiconductor material, or other semiconductor materials known in the art. The substrate can have a major surface 7, which may be, for example, a topmost surface of the substrate semiconductor layer 9. The major surface 7 may be a semiconductor surface. In one embodiment, the major surface 7 may be a single crystalline semiconductor surface, such as a single crystalline semiconductor surface.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁵ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to have electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁵ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

In one embodiment, at least one semiconductor device 700 for a peripheral circuitry may be formed on a portion of the substrate semiconductor layer 9. The at least one semiconductor device can include, for example, field effect transistors. For example, at least one shallow trench isolation structure 720 may be formed by etching portions of the substrate semiconductor layer 9 and depositing a dielectric material therein. A gate dielectric layer, at least one gate conductor layer, and a gate cap dielectric layer may be formed over the substrate semiconductor layer 9, and may be subsequently patterned to form at least one gate structure (750, 752, 754, 758), each of which can include a gate dielectric 750, a gate electrode (752, 754), and a gate cap dielectric 758. The gate electrode (752, 754) may include a stack of a first gate electrode portion 752 and a second gate electrode portion 754. At least one gate spacer 756 may be formed around the at least one gate structure (750, 752, 754, 758) by depositing and anisotropically etching a dielectric liner. Active regions 730 may be formed in upper portions of the substrate semiconductor layer 9, for example, by introducing electrical dopants employing the at least one gate structure (750, 752, 754, 758) as masking structures. Additional masks may be employed as needed. The active region 730 can include source regions and drain regions of field effect transistors. A first dielectric liner 761 and a second dielectric liner 762 may be optionally formed. Each of the first and second dielectric liners (761, 762) can comprise a silicon oxide layer, a silicon nitride layer, and/or a dielectric metal oxide layer. As used herein, silicon oxide includes silicon dioxide as well as non-stoichiometric silicon oxides having more or less than two oxygen atoms for each silicon atoms. Silicon dioxide is preferred. In an illustrative example, the first dielectric liner 761 may be a silicon oxide layer, and the second dielectric liner 762 may be a silicon nitride layer. The least one semiconductor device for the peripheral circuitry can contain a driver circuit for memory devices to be subsequently formed, which can include at least one NAND device.

A dielectric material such as silicon oxide may be deposited over the at least one semiconductor device, and may be subsequently planarized to form a planarization dielectric layer 770. In one embodiment the planarized top surface of the planarization dielectric layer 770 may be coplanar with a top surface of the dielectric liners (761, 762). Subsequently, the planarization dielectric layer 770 and the dielectric liners (761, 762) may be removed from an area to physically expose a top surface of the substrate semiconductor layer 9. As used herein, a surface is “physically exposed” if the surface is in physical contact with vacuum, or a gas phase material (such as air).

The optional semiconductor material layer 10, if present, may be formed on the top surface of the substrate semiconductor layer 9 prior to, or after, formation of the at least one semiconductor device 700 by deposition of a single crystalline semiconductor material, for example, by selective epitaxy. The deposited semiconductor material may be the same as, or may be different from, the semiconductor material of the substrate semiconductor layer 9. The deposited semiconductor material may be any material that may be employed for the substrate semiconductor layer 9 as described above. The single crystalline semiconductor material of the semiconductor material layer 10 may be in epitaxial alignment with the single crystalline structure of the substrate semiconductor layer 9. Portions of the deposited semiconductor material located above the top surface of the planarization dielectric layer 770 may be removed, for example, by chemical mechanical planarization (CMP). In this case, the semiconductor material layer 10 can have a top surface that is coplanar with the top surface of the planarization dielectric layer 770.

The region (i.e., area) of the at least one semiconductor device 700 is herein referred to as a peripheral device region 200. The region in which a memory array is subsequently formed is herein referred to as a memory array region 100. A staircase region 300 for subsequently forming stepped terraces of electrically conductive layers may be provided between the memory array region 100 and the peripheral device region 200. In an alternative embodiment, the at least one semiconductor device 700 is formed under the memory array region 100 in a CMOS under array (“CUA”) configuration. In this case, the peripheral device region 200 may be omitted or used in combination with the CUA configuration. In another alternative embodiment, the at least one semiconductor device 700 may be formed on a separate substrate and then bonded to substrate (9, 10) containing the memory array region 100.

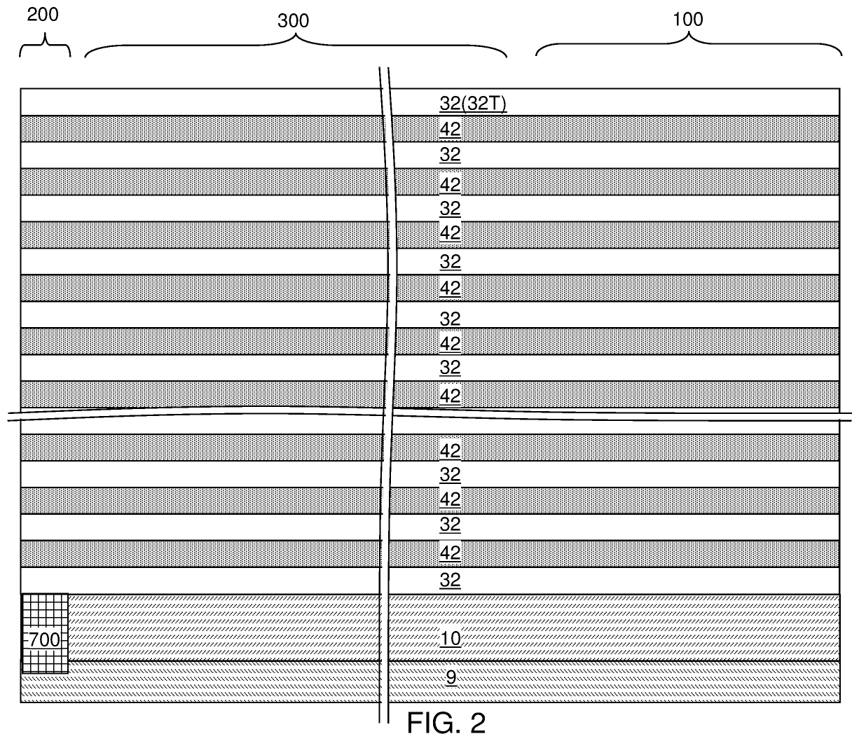

Referring to FIG. 2, a stack of an alternating plurality of first material layers (which may be insulating layers 32) and second material layers (which may be sacrificial material layer 42) is formed over the top surface of the substrate (9, 10). As used herein, a “material layer” refers to a layer including a material throughout the entirety thereof. As used herein, an alternating plurality of first elements and second elements refers to a structure in which instances of the first elements and instances of the second elements alternate. Each instance of the first elements that is not an end element of the alternating plurality is adjoined by two instances of the second elements on both sides, and each instance of the second elements that is not an end element of the alternating plurality is adjoined by two instances of the first elements on both ends. The first elements may have the same thickness thereamongst, or may have different thicknesses. The second elements may have the same thickness thereamongst, or may have different thicknesses. The alternating plurality of first material layers and second material layers may begin with an instance of the first material layers or with an instance of the second material layers, and may end with an instance of the first material layers or with an instance of the second material layers. In one embodiment, an instance of the first elements and an instance of the second elements may form a unit that is repeated with periodicity within the alternating plurality.

Each first material layer includes a first material, and each second material layer includes a second material that is different from the first material. In one embodiment, each first material layer may be an insulating layer 32, and each second material layer may be a sacrificial material layer. In this case, the stack can include an alternating plurality of insulating layers 32 and sacrificial material layers 42, and constitutes a prototype stack of alternating layers comprising insulating layers 32 and sacrificial material layers 42.

The stack of the alternating plurality is herein referred to as an alternating stack (32, 42). In one embodiment, the alternating stack (32, 42) can include insulating layers 32 composed of the first material, and sacrificial material layers 42 composed of a second material different from that of insulating layers 32. The first material of the insulating layers 32 may be at least one insulating material. As such, each insulating layer 32 may be an insulating material layer. Insulating materials that may be employed for the insulating layers 32 include, but are not limited to, silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 may be silicon oxide.

The second material of the sacrificial material layers 42 is a sacrificial material that may be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The sacrificial material layers 42 may comprise an insulating material, a semiconductor material, or a conductive material. The second material of the sacrificial material layers 42 may be subsequently replaced with electrically conductive electrodes which can function, for example, as control gate electrodes of a vertical NAND device. Non-limiting examples of the second material include silicon nitride, an amorphous semiconductor material (such as amorphous silicon), and a polycrystalline semiconductor material (such as polysilicon). In one embodiment, the sacrificial material layers 42 may be spacer material layers that comprise silicon nitride or a semiconductor material including at least one of silicon and germanium.

In one embodiment, the insulating layers 32 can include silicon oxide, and sacrificial material layers can include silicon nitride sacrificial material layers. The first material of the insulating layers 32 may be deposited, for example, by chemical vapor deposition (CVD). For example, if silicon oxide is employed for the insulating layers 32, tetraethyl orthosilicate (TEOS) may be employed as the precursor material for the CVD process. The second material of the sacrificial material layers 42 may be formed, for example, CVD or atomic layer deposition (ALD).

The sacrificial material layers 42 may be suitably patterned so that conductive material portions to be subsequently formed by replacement of the sacrificial material layers 42 can function as electrically conductive electrodes, such as the control gate electrodes of the monolithic three-dimensional NAND string memory devices to be subsequently formed. The sacrificial material layers 42 may comprise a portion having a strip shape extending substantially parallel to the major surface 7 of the substrate.

The thicknesses of the insulating layers 32 and the sacrificial material layers 42 may be in a range from 20 nm to 80 nm, although lesser and greater thicknesses may be employed for each insulating layer 32 and for each sacrificial material layer 42. The number of repetitions of the pairs of an insulating layer 32 and a sacrificial material layer 42 may be in a range from 2 to 1,024, and typically from 8 to 256, although a greater number of repetitions can also be employed. In one embodiment, each sacrificial material layer 42 in the alternating stack (32, 42) can have a uniform thickness that is substantially invariant within each respective sacrificial material layer 42.

The topmost layer of the alternating stack (32, 42) may comprise a topmost insulating layer 32T, which is an insulating layer 32 that is located above all other insulating layers 32. The topmost insulating layer 32T includes a dielectric material that is different from the material of the sacrificial material layers 42. In one embodiment, the topmost insulating layer 32T can include a dielectric material that may be employed for the insulating layers 32 as described above. The topmost insulating layer 32T can have a greater thickness than each of the insulating layers 32. The topmost insulating layer 32T may be deposited, for example, by chemical vapor deposition. In one embodiment, the topmost insulating layer 32T may be a silicon oxide layer.

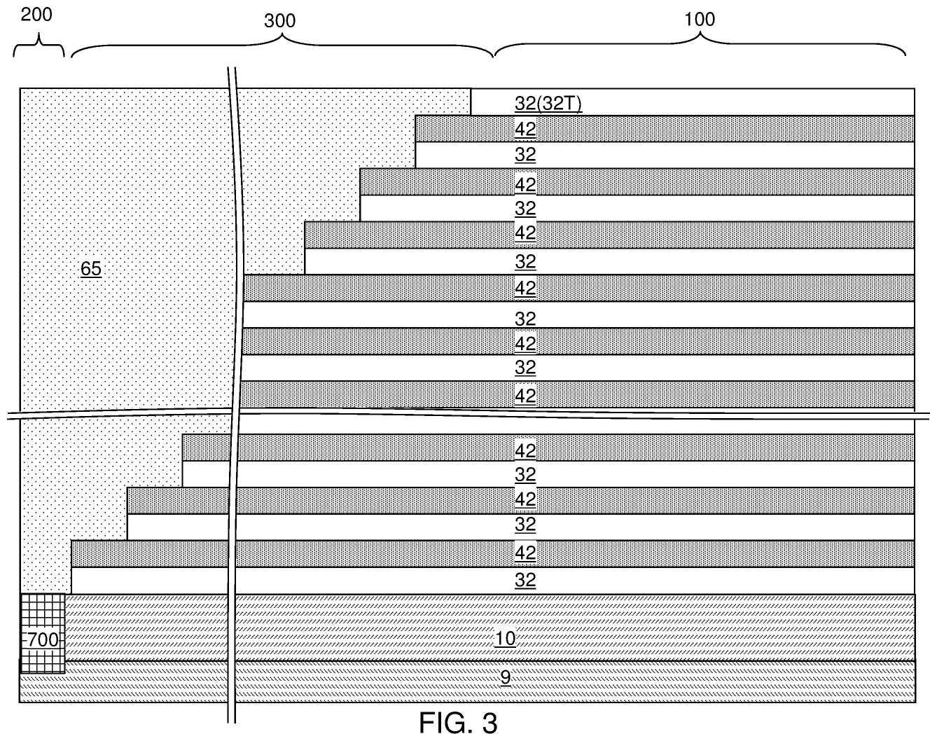

Referring to FIG. 3, stepped surfaces are formed at a peripheral region of the alternating stack (32, 42), which is herein referred to as a terrace region. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The terrace region is formed in the staircase region 300, which is located between the memory array region 100 and the peripheral device region 200 containing the at least one semiconductor device for the peripheral circuitry. The stepped cavity can have various stepped surfaces such that the horizontal cross-sectional shape of the stepped cavity changes in steps as a function of the vertical distance from the top surface of the substrate (9, 10). In one embodiment, the stepped cavity may be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The terrace region includes stepped surfaces of the alternating stack (32, 42) that continuously extend from a bottommost layer within the alternating stack (32, 42) to a topmost layer within the alternating stack (32, 42).

Each vertical step of the stepped surfaces can have the height of one or more pairs of an insulating layer 32 and a sacrificial material layer. In one embodiment, each vertical step can have the height of a single pair of an insulating layer 32 and a sacrificial material layer 42. In another embodiment, multiple “columns” of staircases may be formed along a first horizontal direction hd1 such that each vertical step has the height of a plurality of pairs of an insulating layer 32 and a sacrificial material layer 42, and the number of columns may be at least the number of the plurality of pairs. Each column of staircase may be vertically offset from each other such that each of the sacrificial material layers 42 has a physically exposed top surface in a respective column of staircases. In the illustrative example, two columns of staircases are formed for each block of memory stack structures to be subsequently formed such that one column of staircases provide physically exposed top surfaces for odd-numbered sacrificial material layers 42 (as counted from the bottom) and another column of staircases provide physically exposed top surfaces for even-numbered sacrificial material layers (as counted from the bottom). Configurations employing three, four, or more columns of staircases with a respective set of vertical offsets among the physically exposed surfaces of the sacrificial material layers 42 may also be employed. Each sacrificial material layer 42 has a greater lateral extent, at least along one direction, than any overlying sacrificial material layers 42 such that each physically exposed surface of any sacrificial material layer 42 does not have an overhang. In one embodiment, the vertical steps within each column of staircases may be arranged along the first horizontal direction hd1, and the columns of staircases may be arranged along a second horizontal direction hd2 that is perpendicular to the first horizontal direction hd1. In one embodiment, the first horizontal direction hd1 may be perpendicular to the boundary between the memory array region 100 and the staircase region 300.

A retro-stepped dielectric material portion 65 (i.e., an insulating fill material portion) may be formed in the stepped cavity by deposition of a dielectric material therein. For example, a dielectric material such as silicon oxide may be deposited in the stepped cavity. Excess portions of the deposited dielectric material may be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures 72 may be formed through the topmost insulating layer 32T and a subset of the sacrificial material layers 42 located at drain-select-levels. The drain-select-level isolation structures 72 may be formed, for example, by forming drain-select-level isolation trenches and filling the drain-select-level isolation trenches with a dielectric material such as silicon oxide. Excess portions of the dielectric material may be removed from above the top surface of the topmost insulating layer 32T.

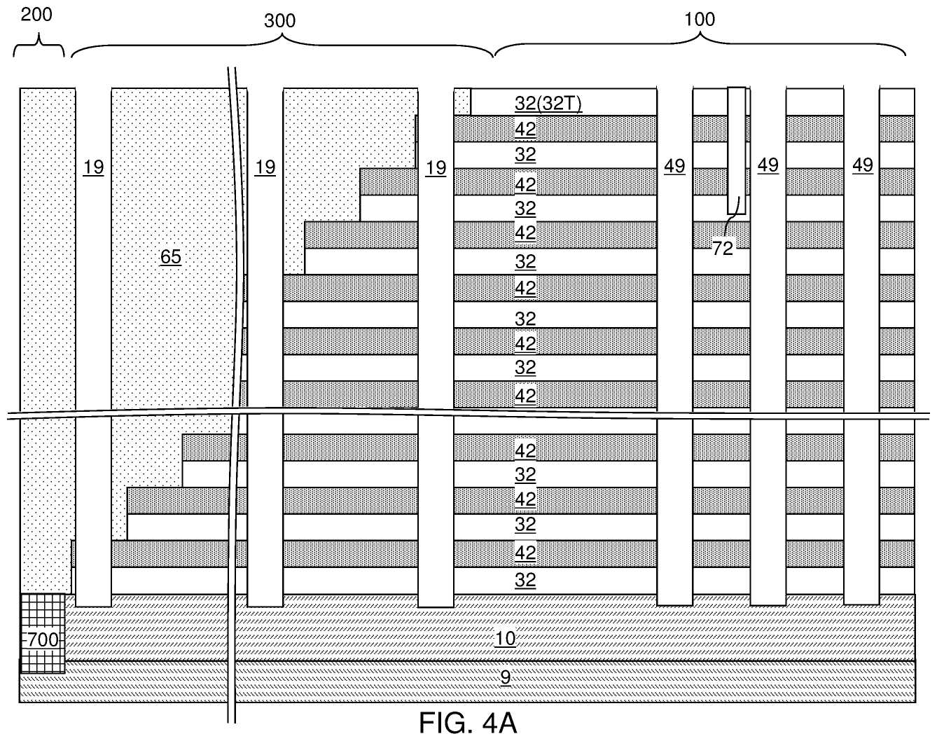

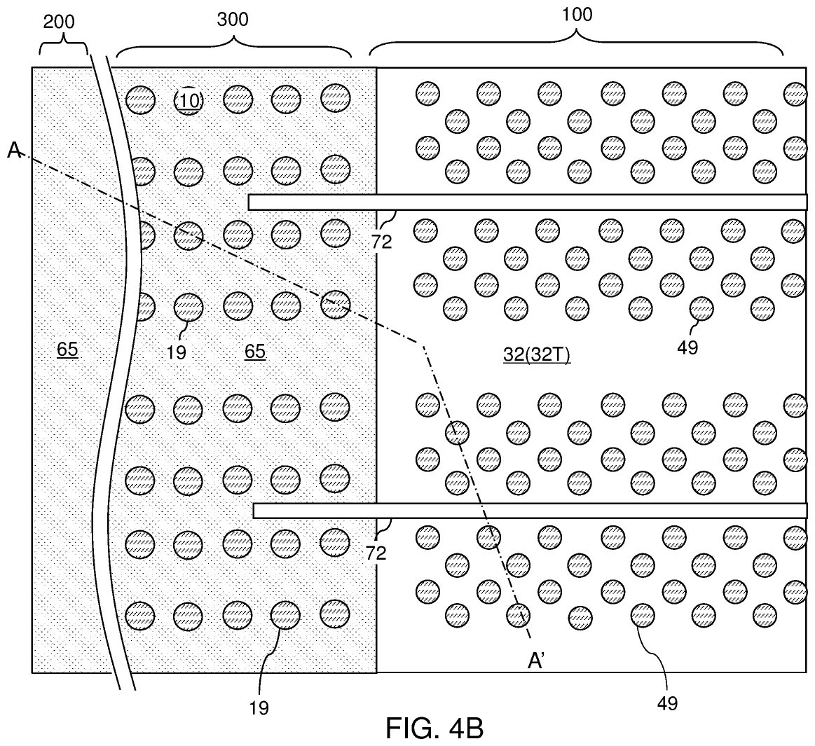

Referring to FIGS. 4A and 4B, a lithographic material stack (not shown) including at least a photoresist layer may be formed over the topmost insulating layer 32T and the retro-stepped dielectric material portion 65, and may be lithographically patterned to form openings therein. The openings include a first set of openings formed over the memory array region 100 and a second set of openings formed over the staircase region 300. The pattern in the lithographic material stack may be transferred through the topmost insulating layer 32T or the retro-stepped dielectric material portion 65, and through the alternating stack (32, 42) by at least one anisotropic etch that employs the patterned lithographic material stack as an etch mask. Portions of the alternating stack (32, 42) underlying the openings in the patterned lithographic material stack are etched to form memory openings 49 and support openings 19. As used herein, a “memory opening” refers to a structure in which memory elements, such as a memory stack structure, is subsequently formed. As used herein, a “support opening” refers to a structure in which a support structure (such as a support pillar structure) that mechanically supports other elements is subsequently formed. The memory openings 49 are formed through the topmost insulating layer 32T and the entirety of the alternating stack (32, 42) in the memory array region 100. The support openings 19 are formed through the retro-stepped dielectric material portion 65 and the portion of the alternating stack (32, 42) that underlie the stepped surfaces in the staircase region 300.

The memory openings 49 extend through the entirety of the alternating stack (32, 42). The support openings 19 extend through a subset of layers within the alternating stack (32, 42). The chemistry of the anisotropic etch process employed to etch through the materials of the alternating stack (32, 42) can alternate to optimize etching of the first and second materials in the alternating stack (32, 42). The anisotropic etch may be, for example, a series of reactive ion etches. The sidewalls of the memory openings 49 and the support openings 19 may be substantially vertical, or may be tapered. The patterned lithographic material stack may be subsequently removed, for example, by ashing.

The memory openings 49 and the support openings 19 can extend from the top surface of the alternating stack (32, 42) to at least the horizontal plane including the topmost surface of the semiconductor material layer 10. In one embodiment, an overetch into the semiconductor material layer 10 may be optionally performed after the top surface of the semiconductor material layer 10 is physically exposed at a bottom of each memory opening 49 and each support opening 19. The overetch may be performed prior to, or after, removal of the lithographic material stack. In other words, the recessed surfaces of the semiconductor material layer 10 may be vertically offset from the un-recessed top surfaces of the semiconductor material layer 10 by a recess depth. The recess depth may be, for example, in a range from 1 nm to 50 nm, although lesser and greater recess depths can also be employed. The overetch is optional, and may be omitted. If the overetch is not performed, the bottom surfaces of the memory openings 49 and the support openings 19 may be coplanar with the topmost surface of the semiconductor material layer 10.

Each of the memory openings 49 and the support openings 19 may include a sidewall (or a plurality of sidewalls) that extends substantially perpendicular to the topmost surface of the substrate. A two-dimensional array of memory openings 49 may be formed in the memory array region 100. A two-dimensional array of support openings 19 may be formed in the staircase region 300. The substrate semiconductor layer 9 and the semiconductor material layer 10 collectively constitutes a substrate (9, 10), which may be a semiconductor substrate. Alternatively, the semiconductor material layer 10 may be omitted, and the memory openings 49 and the support openings 19 may be extend to a top surface of the substrate semiconductor layer 9.

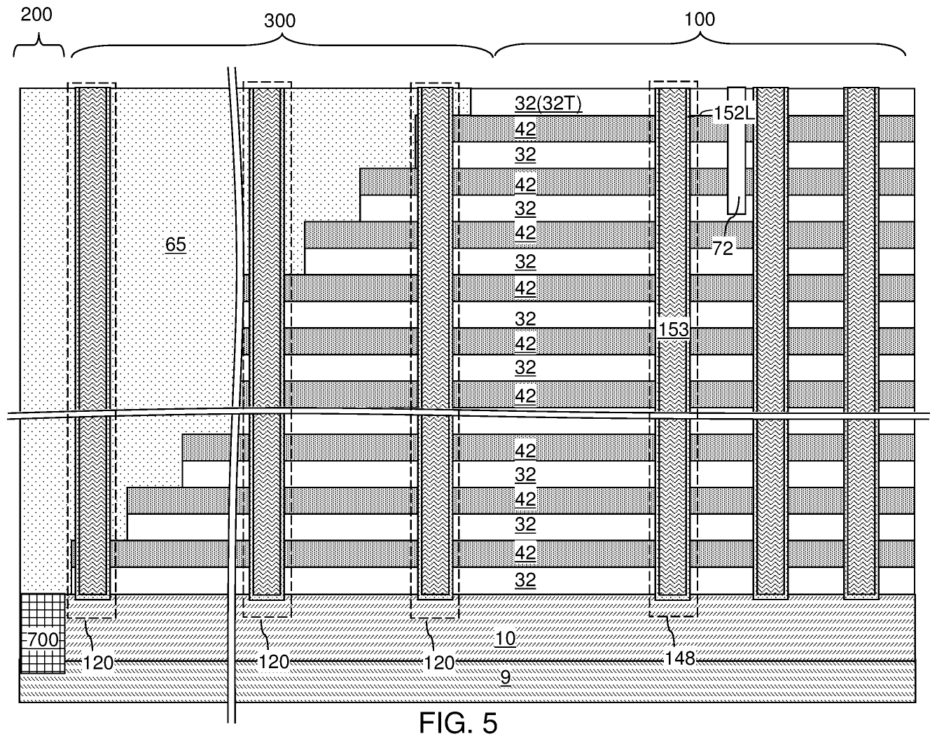

Referring to FIG. 5, a dielectric material liner layer can be conformally deposited at peripheries of the memory openings 49 and the support openings 19 and over the top surface of the topmost insulating layer 32T. The dielectric material liner layer comprises a dielectric material that can provide methyl group-terminated surfaces, i.e., —CH₃ terminated surfaces. As such, the dielectric material liner layer includes a dielectric material that contains a methyl group in the molecular structure. For example, the dielectric material liner layer may comprise, and/or may consist essentially of, organosilicate glass comprising Si, C, 0, and H (e.g., hydrogen doped silicon oxycarbide, SiCOH). Generally, any organosilicate glass material known in the art may be employed for the dielectric material liner layer. The thickness of the dielectric material liner layer may be in a range from 1 nm to 30 nm, such as from 3 nm to 10 nm, although lesser and greater thicknesses may also be employed.

A sacrificial fill material can be subsequently deposited in remaining volumes of the memory openings 49 and the support openings. The sacrificial fill material may comprise a carbon-based material, such as amorphous carbon or diamond-like carbon (DLC), a semiconductor material, such as amorphous silicon or a silicon-germanium alloy, or a polymer material that may be subsequently removed selective to the material of the dielectric material liner layer.

A planarization process such as a chemical mechanical polishing (CMP) process and/or a recess etch process may be performed to remove excess portions of the sacrificial fill material and the material of the dielectric material liner layer from above the horizontal plane including the top surface of the topmost insulating layer 32T. Each remaining portion of the dielectric material liner layer constitutes a dielectric material liner 152L. Each remaining portion of the sacrificial fill material constitutes a sacrificial fill material portion 153. Each contiguous combination of a dielectric material liner 152L and a sacrificial fill material portion 153 that fills a memory opening 49 constitutes a sacrificial memory opening fill structure 148. Each contiguous combination of a dielectric material liner 152L and a sacrificial fill material portion 153 that fills a support opening 19 constitutes a sacrificial support pillar structure 120.

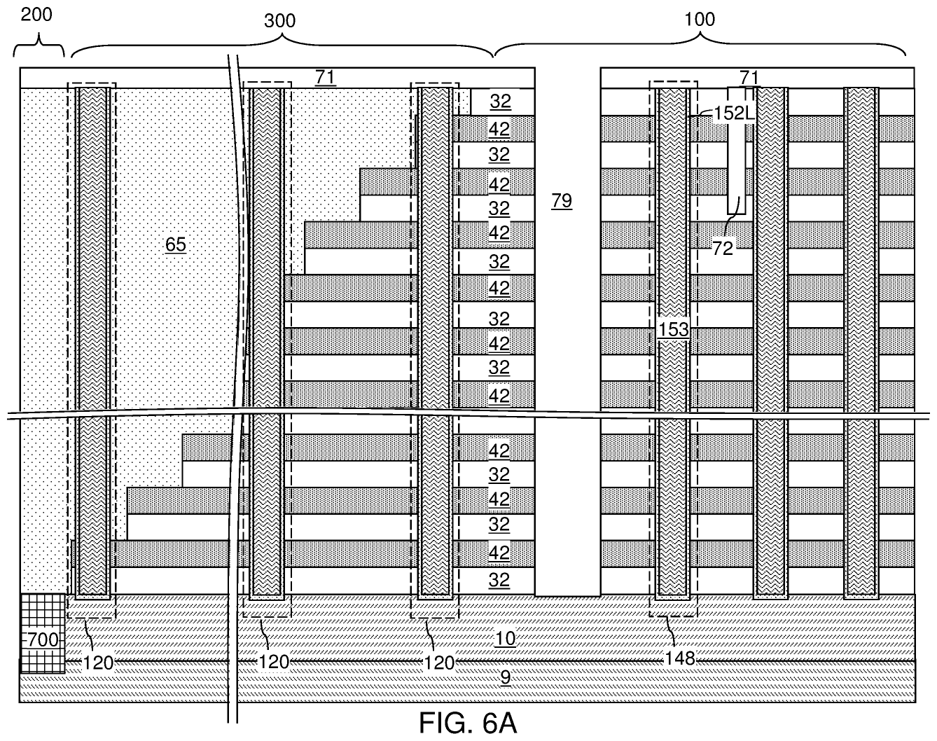

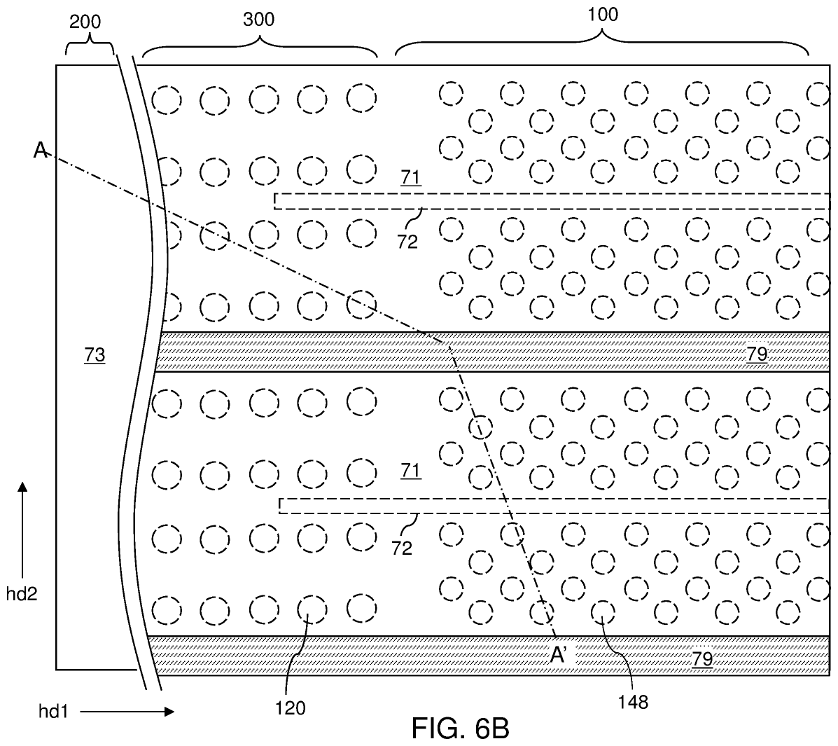

Referring to FIGS. 6A and 6B, a sacrificial cover layer 71 may be formed over the alternating stack (32, 42) and the retro-stepped dielectric material portion 65. The sacrificial cover layer 71 comprises a dielectric material such as silicon oxide. The thickness of the sacrificial cover layer 71 may be in a range from 10 nm to 300 nm, such as from 30 nm to 100 nm, although lesser and greater thicknesses may also be employed.

A photoresist layer (not shown) may be applied over the sacrificial cover layer 71, and is lithographically patterned to form openings in areas between clusters of sacrificial memory opening fill structures 148. The pattern in the photoresist layer may be transferred through the sacrificial cover layer 71, the alternating stack (32, 42) and/or the retro-stepped dielectric material portion 65 employing an anisotropic etch to form backside trenches 79, which vertically extend from the top surface of the sacrificial cover layer 71 at least to the top surface of the substrate (9, 10), and laterally extend through the memory array region 100 and the staircase region 300.

In one embodiment, the backside trenches 79 can laterally extend along a first horizontal direction hd1 and may be laterally spaced apart from each other along a second horizontal direction hd2 that is perpendicular to the first horizontal direction hd1. The sacrificial memory opening fill structures 148 may be arranged in rows that extend along the first horizontal direction hd1. The drain-select-level isolation structures 72 can laterally extend along the first horizontal direction hd1. Each backside trench 79 can have a uniform width that is invariant along the lengthwise direction (i.e., along the first horizontal direction hd1). Each drain-select-level isolation structure 72 can have a uniform vertical cross-sectional profile along vertical planes that are perpendicular to the first horizontal direction hd1 that is invariant with translation along the first horizontal direction hd1. Multiple rows of sacrificial memory opening fill structures 148 may be located between a neighboring pair of a backside trench 79 and a drain-select-level isolation structure 72, or between a neighboring pair of drain-select-level isolation structures 72. In one embodiment, the backside trenches 79 can include a source contact opening in which a source contact via structure may be subsequently formed. The photoresist layer may be removed, for example, by ashing.

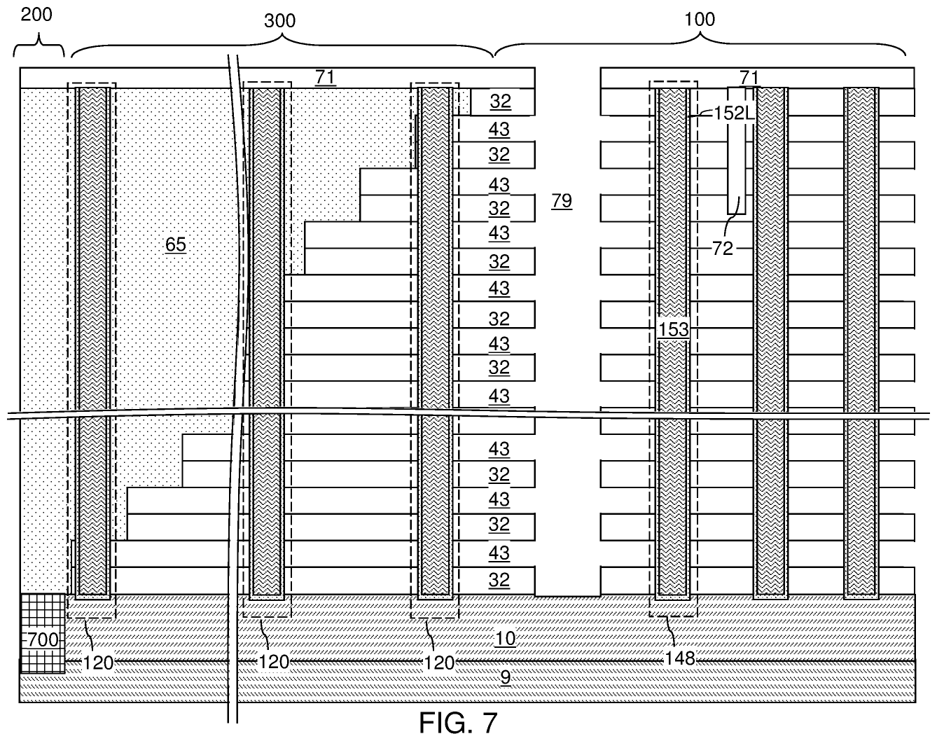

Referring to FIG. 7, an etchant that selectively etches the second material of the sacrificial material layers 42 with respect to the first material of the insulating layers 32 can be introduced into the backside trenches 79, for example, employing an etch process. Backside recesses 43 are formed in volumes from which the sacrificial material layers 42 are removed. The removal of the second material of the sacrificial material layers 42 can be selective to the first material of the insulating layers 32, the material of the retro-stepped dielectric material portion 65, the semiconductor material of the semiconductor material layer 10, and the dielectric material liners 152L. In one embodiment, the sacrificial material layers 42 can include silicon nitride, and the materials of the insulating layers 32 and the retro-stepped dielectric material portion 65 can be selected from silicon oxide and dielectric metal oxides. Outer surface segments of each dielectric material liners 152L can be physically exposed to the backside recesses 43.

The etch process that removes the second material selective to the first material and the dielectric material liners 152L can be a wet etch process employing a wet etch solution, or can be a gas phase (dry) etch process in which the etchant is introduced in a vapor phase into the backside trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art. The sacrificial support pillar structures 120, the retro-stepped dielectric material portion 65, and the sacrificial memory opening fill structure 148 provide structural support while the backside recesses 43 are present within volumes previously occupied by the sacrificial material layers 42.

Each backside recess 43 can be a laterally extending cavity having a lateral dimension that is greater than the vertical extent of the cavity. In other words, the lateral dimension of each backside recess 43 can be greater than the height of the backside recess 43. A plurality of backside recesses 43 can be formed in the volumes from which the second material of the sacrificial material layers 42 is removed. The memory openings in which the sacrificial memory opening fill structures 148 are formed are herein referred to as front side openings or front side cavities in contrast with the backside recesses 43. In one embodiment, the memory array region 100 comprises an array of three-dimensional NAND strings having a plurality of device levels disposed above the substrate (9, 10). In this case, each backside recess 43 can define a space for receiving a respective word line of the array of three-dimensional NAND strings.

Each of the plurality of backside recesses 43 can extend substantially parallel to the top surface of the substrate (9, 10). A backside recess 43 can be vertically bounded by a top surface of an underlying insulating layer 32 and a bottom surface of an overlying insulating layer 32. In one embodiment, each backside recess 43 can have a uniform height throughout.

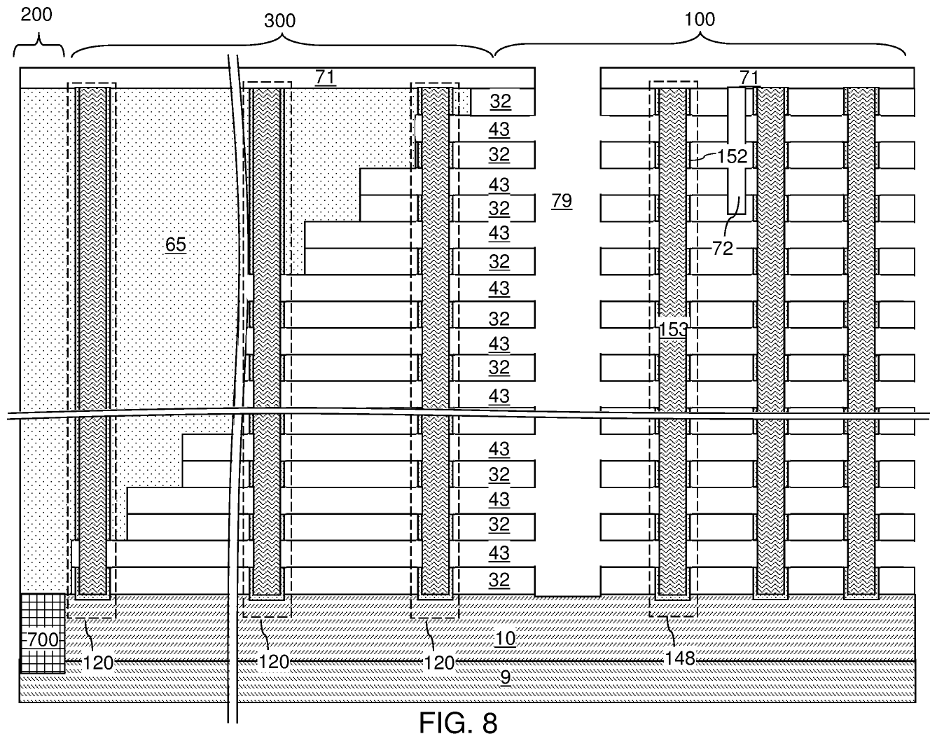

Referring to FIG. 8, an isotropic etch process can be performed to etch physically exposed surface portions of the dielectric material liners 152L around the backside recesses 43. The isotropic etch process may be a wet etch process that etches the material of the dielectric material liners 152L at a higher etch rate than the material of the insulating layers 32. For example, if the dielectric material liners 152L comprise organosilicate glass, the isotropic etch process may comprise a wet etch process employing dilute hydrofluoric acid (DHF). The duration of the isotropic etch process can be selected such that the etch distance is greater than the thickness of the dielectric material liners 152L.

Generally, the backside recesses 43 can be laterally expanded by removing portions of the dielectric material liners 152L around the backside recesses 43. Remaining portions of the dielectric material liners 152L comprise vertical stacks of tubular dielectric material portions 152. Thus, each dielectric material liner 152L can be divided into a respective vertical stack of dielectric material portions that include tubular dielectric material portions 152. A vertical stack of tubular dielectric material portions 152 located at the vertical levels of the insulating layers 32 can be formed around each sacrificial opening fill material portions 153 located within a respective one of the memory openings. A subset of the sacrificial support pillar structures 120 may comprise a respective sacrificial opening fill material portion 153 and at least one tubular dielectric material portion 152.

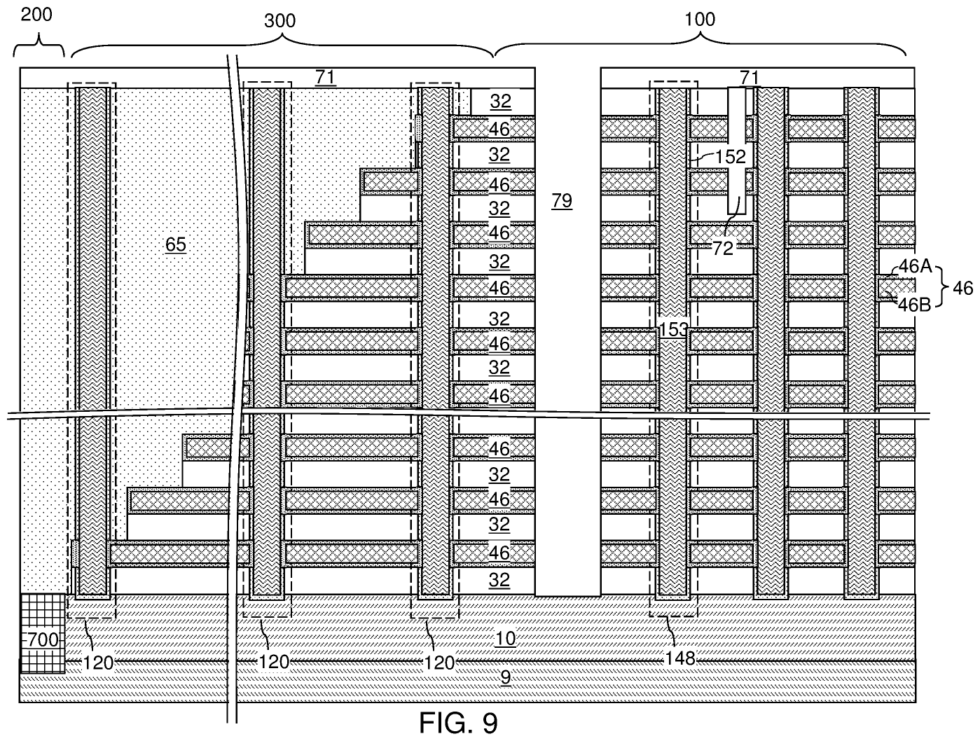

Referring to FIG. 9, at least one metallic fill material can be deposited in the backside recesses 43 and in peripheral portions of the backside trenches 79 and over the sacrificial cover layer 71. In one embodiment, the at least one metallic fill material may comprise a metallic barrier material and a metallic fill material.

For example, a metallic barrier layer 46A can be deposited in the backside recesses 43. The metallic barrier layer 46A includes an electrically conductive metallic material that can function as a diffusion barrier layer and/or adhesion promotion layer for a metallic fill material to be subsequently deposited. The metallic barrier layer 46A can include a conductive metallic nitride material such as TiN, TaN, WN, or a stack thereof, or can include a conductive metallic carbide material such as TiC, TaC, WC, or a stack thereof. In one embodiment, the metallic barrier layer 46A can be deposited by a conformal deposition process such as chemical vapor deposition (CVD) or atomic layer deposition (ALD). The thickness of the metallic barrier layer 46A can be in a range from 2 nm to 8 nm, such as from 3 nm to 6 nm, although lesser and greater thicknesses can also be employed. In one embodiment, the metallic barrier layer 46A can consist essentially of a conductive metal nitride such as TiN.

A metal fill material can be subsequently deposited over the metallic barrier layer 46A to form a metallic fill material layer 46B. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer 46B can consist essentially of at least one elemental metal. The at least one elemental metal of the metallic fill material layer 46B can be selected, for example, from tungsten, cobalt, ruthenium, titanium, and tantalum. In one embodiment, the metallic fill material layer 46B can consist essentially of a single elemental metal. In one embodiment, the metallic fill material layer 46B can be deposited employing a fluorine-containing precursor gas such as WF₆. In one embodiment, the metallic fill material layer 46B can be a tungsten layer including a residual level of fluorine atoms as impurities. The metallic fill material layer 46B is spaced from the insulating layers 32 and the sacrificial memory opening fill structures 148 by the metallic barrier layer 46A, which is a diffusion barrier layer that blocks diffusion of fluorine atoms therethrough.

A continuous metallic material layer can be formed on the sidewalls of each backside trench 79 and over the sacrificial cover layer 71. The continuous electrically conductive material layer can be etched back from the sidewalls of each backside trench 79 and from above the sacrificial cover layer 71, for example, by an isotropic wet etch, an anisotropic dry etch, or a combination thereof. Each remaining portion of the deposited metallic material in the backside recesses 43 constitutes an electrically conductive layer 46. Each electrically conductive layer 46 can be a conductive line structure. Thus, the sacrificial material layers 42 are replaced with the electrically conductive layers 46.

Each sacrificial material layer 42 can be replaced with an electrically conductive layer 46. Each electrically conductive layer 46 includes a portion of the metallic barrier layer 46A and a portion of the metallic fill material layer 46B that are located between a vertically neighboring pair of insulating layers 32.

The vertical stack of tubular dielectric material portions 152 comprises physically exposed —CH₃ terminated surfaces. In one embodiment, the electrically conductive layers 46 and the vertical stacks of tubular dielectric material portions 152 may be formed such that cylindrical sidewalls of the electrically conductive layers 46 around each memory opening are vertically coincident with cylindrical inner sidewalls of the tubular dielectric material portions 152. In one embodiment, the tubular dielectric material portions 152 comprise organosilicate glass.

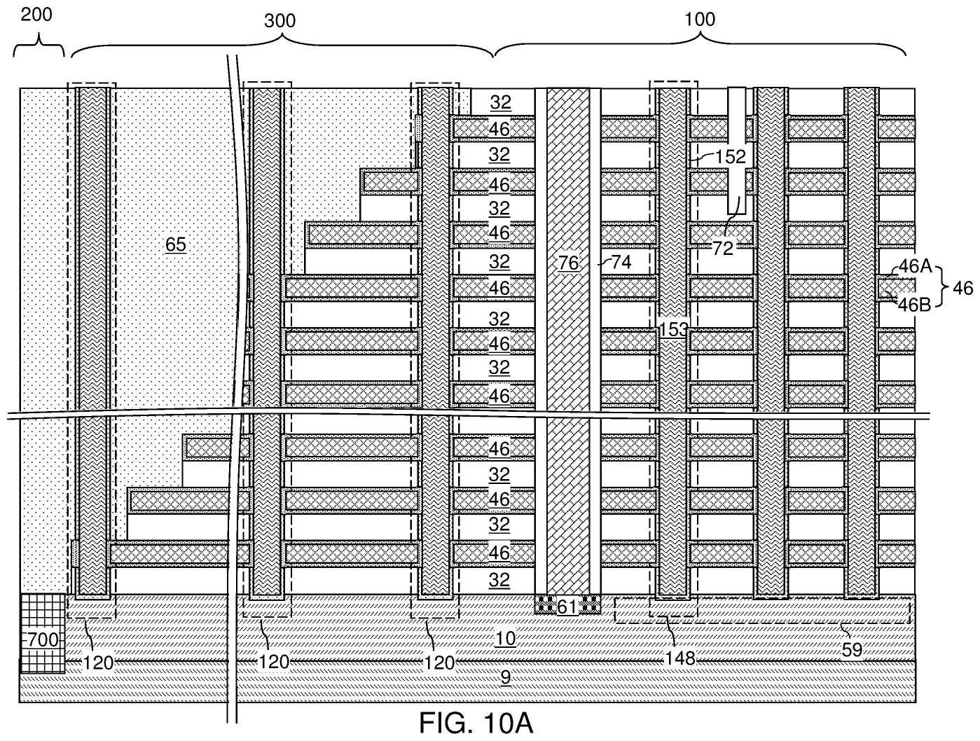

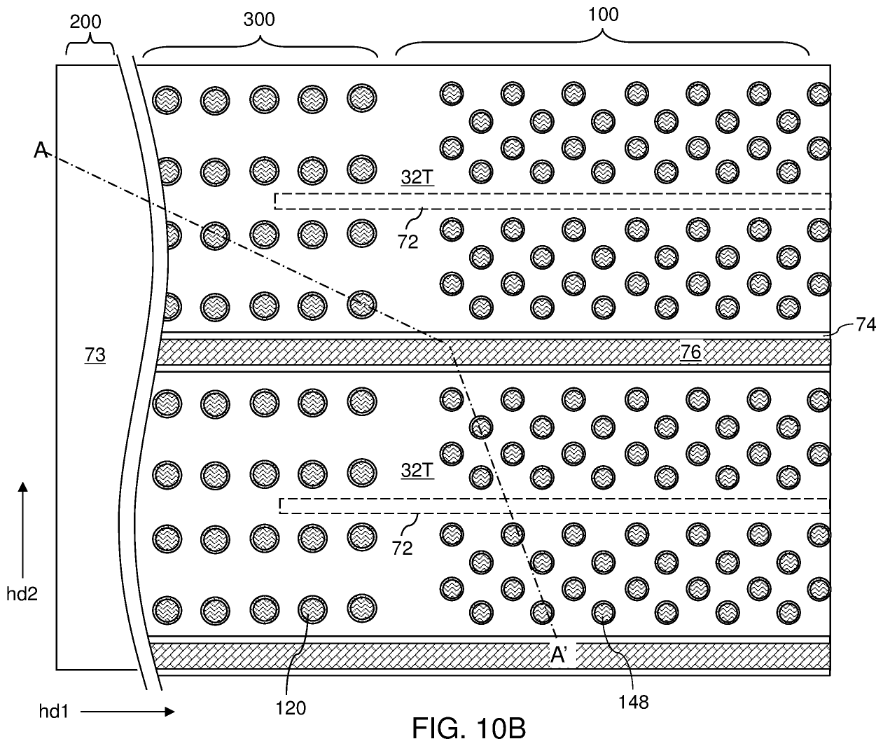

Referring to FIGS. 10A and 10B, dopants of a second conductivity type can be implanted into surface portions of the semiconductor material layer 10 that underlie the backside trenches 79. The second conductivity type is the opposite of the first conductivity type. For example, if the first conductivity type is p-type, the second conductivity type is n-type, and vice versa. Each implanted portion of the semiconductor material layer 10 can be converted into a source region 61. Each surface portion of the semiconductor material layer 10 located between the source regions 61 and adjacent bottom surfaces of the sacrificial memory opening fill structures 148 constitutes a horizontal semiconductor channel 59.

An insulating material layer can be conformally deposited in the backside trenches 79 and over the sacrificial cover layer. The insulating material layer may comprise a planarizable dielectric material such as silicon oxide. An anisotropic etch process can be performed to remove horizontally-extending portions of the insulating material layer. Each remaining vertically-extending portion of the insulating material layer located in a respective one of the backside trenches 79 comprise a backside insulating spacer 74.

At least one conductive material in the remaining unfilled volumes of the backside trenches 79 and over the sacrificial cover layer 71. For example, the at least one conductive material can include an optional conductive liner and a conductive fill material portion. The conductive liner can include a conductive metallic liner such as TiN, TaN, WN, TiC, TaC, WC, an alloy thereof, or a stack thereof. The thickness of the conductive liner can be in a range from 3 nm to 30 nm, although lesser and greater thicknesses can also be employed. The conductive fill material portion can include a metal or a metal alloy. For example, the conductive fill material portion can include Mo, W, Cu, Al, Co, Ru, Ni, an alloy thereof, or a stack thereof.

Portions of the at least one conductive material, the backside insulating spacers 74, and the sacrificial cover layer 71 may be removed from above the horizontal plane including the top surface of the topmost insulating layer 32 by performing a planarization process. The planarization process may comprise at least one recess etch process and/or a chemical mechanical polishing (CMP) process. Each remaining portion of the at least one conductive material filling a respective backside trench 79 constitutes a backside contact via structure 76. In one embodiment, top surfaces of the backside contact via structures 76 and the backside insulating spacers 74 may be formed within the horizontal plane including the topmost surface of the topmost insulating layer 32.

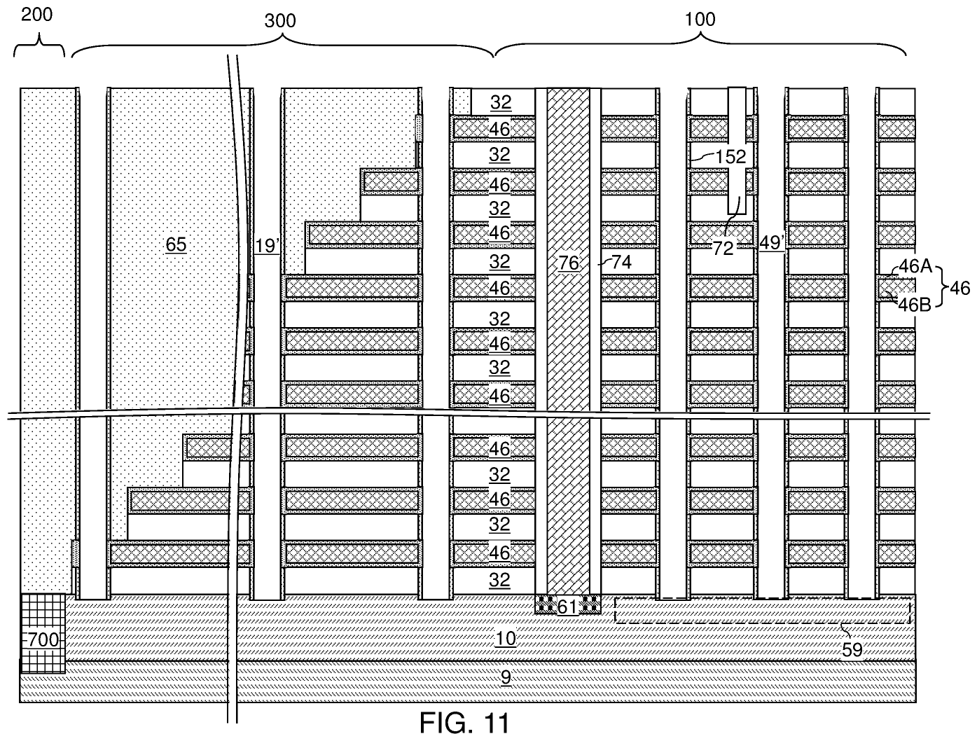

Referring to FIG. 11, the sacrificial fill material portions 153 may be removed selective to the material of the tubular dielectric material portions 152 and the electrically conductive layers 46. For example, if the sacrificial fill material portions 153 comprise a carbon-based material (such as amorphous carbon), then an ashing process may be performed to remove the tubular dielectric material portions 152. If the sacrificial fill material portions 153 comprise a semiconductor material, such as amorphous silicon, an isotropic etch process employing tetramethyl ammonium hydroxide (TMAH) or hot trimethyl-2 hydroxyethyl ammonium hydroxide (“hot TMY”) may be employed to remove the sacrificial fill material portions 153. A memory cavity 49′ is formed within each memory opening 49. A support cavity 19′ may be formed within each support opening 19. An anisotropic etch process may be performed to remove horizontally-extending remaining portions of the dielectric material liners 152L at the bottom of the memory openings 49 and the support openings 19. A top surface of the semiconductor material layer 10 can be physically exposed at the bottom of each memory opening 49 and at the bottom of each support opening 19. A memory cavity 49′ is present within each memory opening 49, and a support cavity 19′ is present within each support opening 19.

Generally, a combination of an alternating stack of insulating layers 32 and electrically conductive layers 46 having at least one opening therethrough and at least one vertical stack of tubular dielectric material portions 152 can be formed. Each of the at least one vertical stack of tubular dielectric material portions 152 can be located at a periphery of a respective opening at a level of a respective one of the insulating layers 32. In one embodiment, the inner cylindrical sidewalls of a vertical stack of tubular dielectric material portions 152 around a memory cavity 49′ may be vertically coincident with cylindrical sidewalls of the electrically conductive layers 46 around the memory cavity 49′.

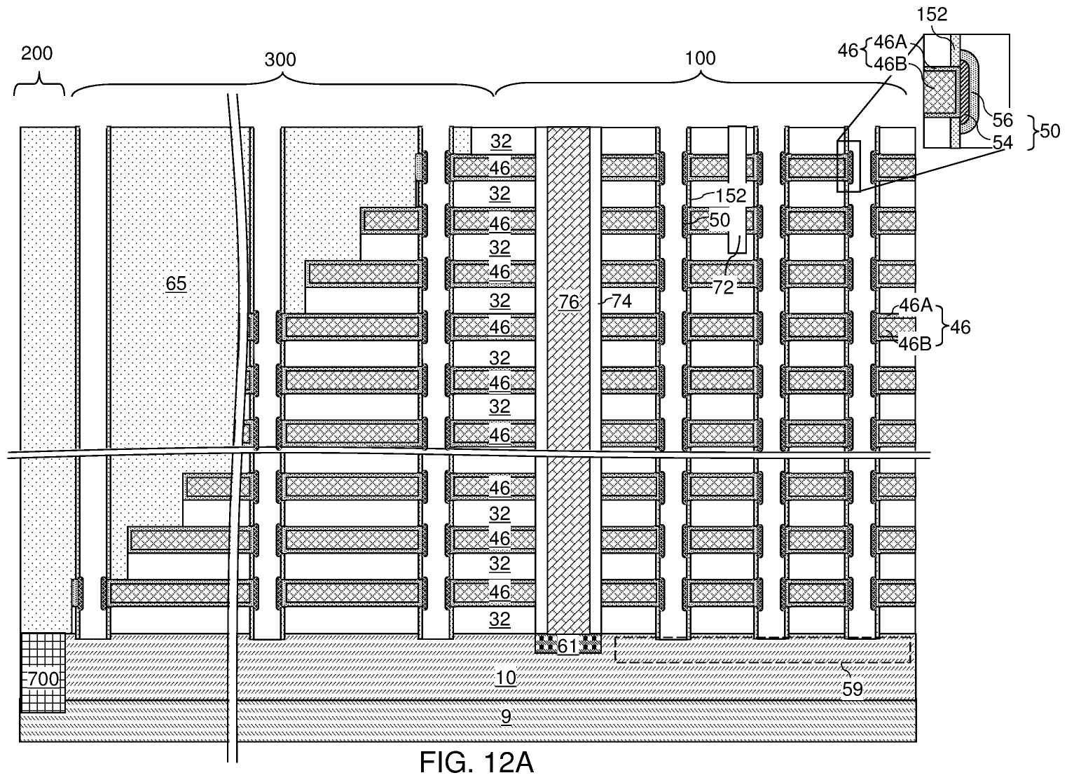

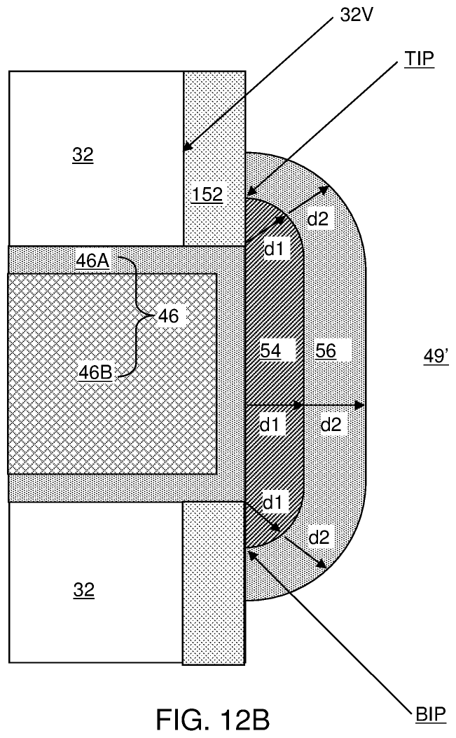

Referring to FIGS. 12A and 12B and according to an aspect of the present disclosure, a selective ferroelectric material deposition process can be performed to grow dielectric ferroelectric material portions 54 from physically exposed metallic surfaces of the electrically conductive layers 46 while suppressing growth of any dielectric ferroelectric material from physically exposed dielectric surfaces such as the surfaces of the tubular dielectric material portions 152. The selective ferroelectric material deposition process may employ an atomic layer deposition process or a chemical vapor deposition process. The atomic layer deposition process may grow a dielectric ferroelectric material from the physically exposed metallic surfaces of the electrically conductive layers 46 layer by layer in each deposition cycle. The chemical vapor deposition process may continuously grow a dielectric ferroelectric material from the physically exposed metallic surfaces of the electrically conductive layers 46. Alternatively, a combination of an atomic layer deposition process and an atomic layer etching process may be performed to grow a dielectric ferroelectric material.

According to an embodiment of the present disclosure, the physically exposed surfaces of the tubular dielectric material portions 152 may comprise —CH₃ terminated hydrophobic surfaces, and the metallic surfaces may comprise hydrogen-terminated (i.e., —H terminated) hydrophilic surfaces. The difference in the termination of the surfaces between the tubular dielectric material portions 152 and the electrically conductive layers 46 may be advantageously employed to suppress growth of the dielectric ferroelectric material from the hydrophobic surfaces of the tubular dielectric material portions 152 while facilitating growth of the dielectric ferroelectric material from the physically exposed hydrophilic surfaces of the electrically conductive layers 46. While an embodiment is described in which the tubular dielectric material portions 152 may comprise —CH₃ terminated hydrophobic surfaces, in alternative embodiments, the tubular dielectric material portions 152 may comprise other hydrophobic surfaces, such as methylene (—CH₂⁻), methoxy (—OCH₃), trifluoromethyl (—CF₃) or trifluoromethyl ester (—OCF₃) terminated surfaces.

In one embodiment, the dielectric ferroelectric material of the dielectric ferroelectric material portions 54 may comprise a transition metal oxide material. In one embodiment, the transition metal oxide material comprises a hafnium oxide based material, which comprises doped or undoped hafnium oxide. In an illustrative example, the ferroelectric material layer 80 may include single crystalline hafnium oxide doped with zirconium (also referred to as hafnium-zirconium oxide), silicon, strontium, aluminum, yttrium, germanium and/or gadolinium.

Generally, the vertical stacks of discrete ferroelectric material portions 54 can be formed by performing a selective deposition process in which a ferroelectric material grows from physically exposed surfaces of the electrically conductive layers 46 while suppressing growth of the ferroelectric material from the physically exposed hydrophilic surfaces (e.g., —CH₃ terminated surfaces), such as the inner sidewalls of the tubular dielectric material portions 152. In one embodiment, one, a plurality and/or each of the discrete ferroelectric material portions 54 comprises a respective outer sidewall that is in direct contact with a cylindrical sidewall of a first electrically conductive layer 46 of the electrically conductive layers 46, and an inner sidewall adjoined to the outer sidewall. The entirety of the outer sidewall of each discrete ferroelectric material portions 54 may be located within a cylindrical vertical plane.

In one embodiment shown in FIG. 12B, the discrete ferroelectric material portions 54 protrude inward into the memory opening 49 relative to vertical (e.g., cylindrical) sidewalls 32V of the insulating layers 32. In one embodiment, the inner sidewall of each discrete ferroelectric material portion 54 may comprise a contoured surface. In one embodiment, growth of the ferroelectric material may be isotropic, and the inner sidewall of each discrete ferroelectric material portion 54 may be equidistant from an interface between the outer sidewall and a most proximal electrically conductive layer 46. In one embodiment, the entirety of the inner sidewall of each discrete ferroelectric material portion 54 may be spaced by a first distance d1 from a most proximal point within an interface between an electrically conductive layer 46 and the outer sidewall of the discrete ferroelectric material portion 54. The first distance d1 is the lateral thickness of each discrete ferroelectric material portion 54. The first distance d1 is less than one half of the vertical thickness of the insulating layers 32, and may be in a range from 5 nm to 20 nm, such as from 10 nm to 15 nm, although lesser and greater values may also be employed.

In one embodiment, the inner sidewall of each discrete ferroelectric material portion 54 comprises a cylindrical surface segment located within a cylindrical vertical plane, an upper convex annular surface segment that is adjoined to a top periphery of the cylindrical surface segment, and a lower convex annular surface segment that is adjoined to a bottom periphery of the cylindrical surface segment. In one embodiment, the upper convex annular surface segment has a first radius of curvature in a vertical cross-sectional view, the lower convex annular surface segment has a second radius of curvature in the vertical cross-sectional view, and the first radius of curvature and the second radius of curvature are the same as the first distance d1.

In one embodiment, the entirety of the outer sidewall is located within a cylindrical vertical plane, a top periphery of the outer sidewall coincides with a top periphery of the inner sidewall, and a bottom periphery of the outer sidewall coincides with a bottom periphery of the inner sidewall. In one embodiment, the interface between an electrically conductive layer 46 and the outer sidewall of a respective discrete ferroelectric material portion 54 comprises a cylindrical area having a top interface periphery TIP and a bottom interface periphery BIP. The top interface periphery TIP is spaced from the top periphery of the inner sidewall by the first distance d1. The bottom interface periphery BIP is spaced from the bottom periphery of the inner sidewall by the first distance d1.

Within each memory opening 49, a vertical stack of tubular dielectric material portions 152 can be interlaced with a vertical stack of discrete ferroelectric material portions 54 along a vertical direction. In one embodiment, each tubular dielectric material portion 152 comprises a respective outer cylindrical sidewall that contacts a cylindrical sidewall of a respective one of the insulating layers 32. In one embodiment, each vertical stack of tubular dielectric material portions 152 comprises and/or consists essentially of a material having hydrophilic surfaces, such as —CH₃ terminated surfaces, at interfaces with the vertical stack of discrete ferroelectric material portions 54. In one embodiment, the interfaces between the vertical stack of tubular dielectric material portions 152 and the vertical stack of discrete ferroelectric material portions 54 comprise cylindrical surface strips having a height that is less than one half of an average vertical thickness of the insulating layers 32.

In one embodiment, each vertical stack of tubular dielectric material portions 152 comprises and/or consists essentially of organosilicate glass. In one embodiment, each vertical stack of discrete ferroelectric material portions 54 is in direct contact with cylindrical surface segments of the insulating layers 32.

Subsequently, discrete dielectric metal oxide portions 56 may be optionally selectively grown from the physically exposed surfaces of the discrete ferroelectric material portions 54. The discrete dielectric metal oxide portions 56, if present, comprises a dielectric metal oxide material that is not ferroelectric. For example, the dielectric metal oxide portions 56 may comprise and/or may consist essentially of aluminum oxide. A vertical stack of dielectric metal oxide portions 56 can be formed on each vertical stack of discrete ferroelectric material portion 54.

The vertical stacks of dielectric metal oxide portions 56 may be formed by atomic layer deposition, chemical vapor deposition, or a combination of atomic layer depositions and atomic layer etch processes. The dielectric metal oxide material of the vertical stacks of dielectric metal oxide portions 56 may be isotropically grown by a growth distance, which is herein referred to as a second distance d2. The second distance d2 may be in a range from 10 nm to 40 nm, such as from 20 nm to 30 nm, although lesser and greater values may also be employed.

Each discrete dielectric metal oxide portion 56 can be formed on a respective one of the discrete ferroelectric material portions 54 within a vertical stack of discrete ferroelectric material portions 54. In one embodiment, one, a plurality and/or each of the discrete dielectric metal oxide portions 56 comprises a contoured inner sidewall. Each point within the contoured inner sidewall of a discrete dielectric metal oxide portions 56 is spaced from a most proximal point within an interface between the discrete dielectric metal oxide portion 56 and a respective discrete ferroelectric material portion 54 by a second distance d2.

In one embodiment, an outer sidewall of one, a plurality or each of the discrete dielectric metal oxide portions 56 comprises a contoured annular surface segment that comprises an entirety of the interface between a respective discrete dielectric metal oxide portion 56 and a respective discrete ferroelectric material portion 54; an upper cylindrical surface segment adjoined to a top periphery of the contoured annular surface segment; and a lower cylindrical surface segment adjoined to a bottom periphery of the contoured annular surface segment.

A contiguous combination of a discrete ferroelectric material portion 54 and a discrete dielectric metal oxide portion 56, or a discrete ferroelectric material portion 54 in case discrete dielectric metal oxide portions 56 are omitted, constitutes a tubular memory structure 50. A vertical stack of discrete, vertically separated, tubular memory structure 50 can be formed within each memory opening 49. At least one tubular memory structure 50 may be formed in one or more of the support openings 49.

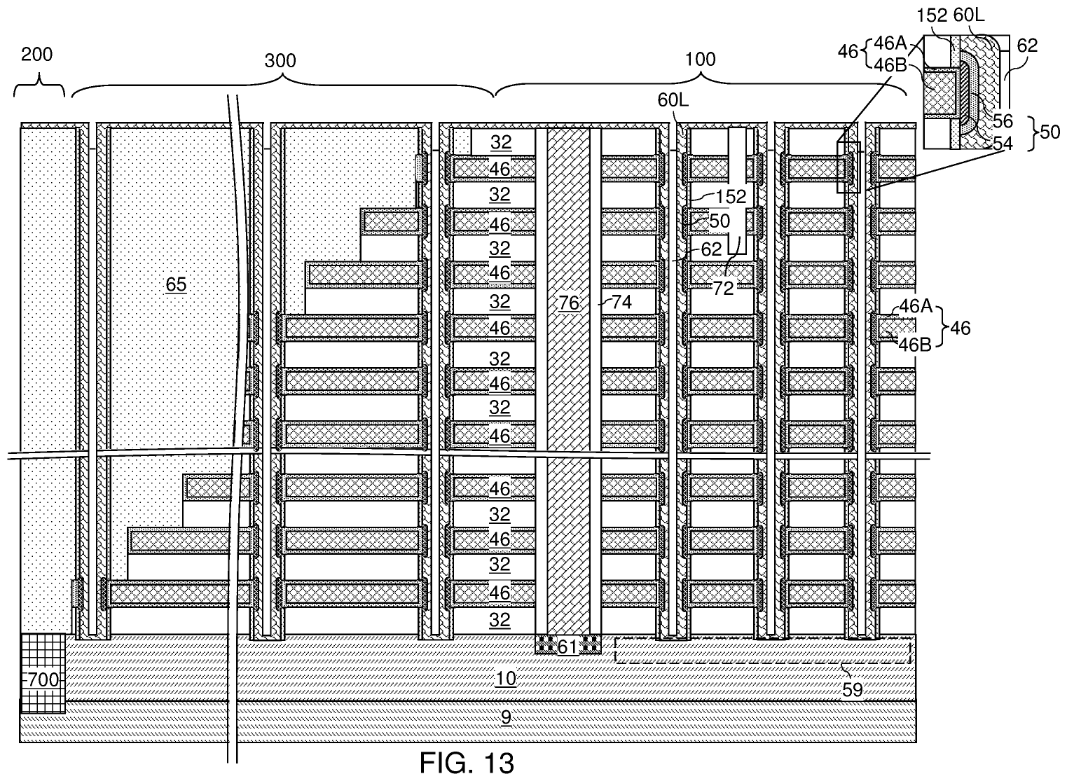

Referring to FIG. 13, a semiconductor channel layer 60L can be deposited directly on the vertical stacks of the discrete dielectric metal oxide portions 56, or directly on the vertical stacks of the discrete ferroelectric material portions 54 in case discrete dielectric metal oxide portions 56 are not employed. The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel layer 60L includes amorphous silicon or polysilicon. The semiconductor channel layer 60L can have a doping of a first conductivity type, which is the same as the conductivity type of the semiconductor material layer 10. The semiconductor channel layer 60L can be formed by a conformal deposition method such as low pressure chemical vapor deposition (LPCVD). The thickness of the semiconductor channel layer 60L can be in a range from 2 nm to 10 nm, although lesser and greater thicknesses can also be employed. The semiconductor channel layer 60L may partially fill the memory cavity in each memory opening 49, or may fully fill the cavity in each memory opening 49.

In case each memory opening 49 is not completely filled by the semiconductor channel layer 60L, a dielectric core layer can be deposited to fill unfilled portions of the memory openings 49. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating. Upper portions of the dielectric core layer can be removed, for example, by performing a recess etch process. Each remaining portion of the dielectric core layer that remains within a respective memory opening 49 constitutes a dielectric core 62. In one embodiment, each dielectric core 62 has a respective top surface that is located below the horizontal plane including the top surface of the insulating cap layer 70.

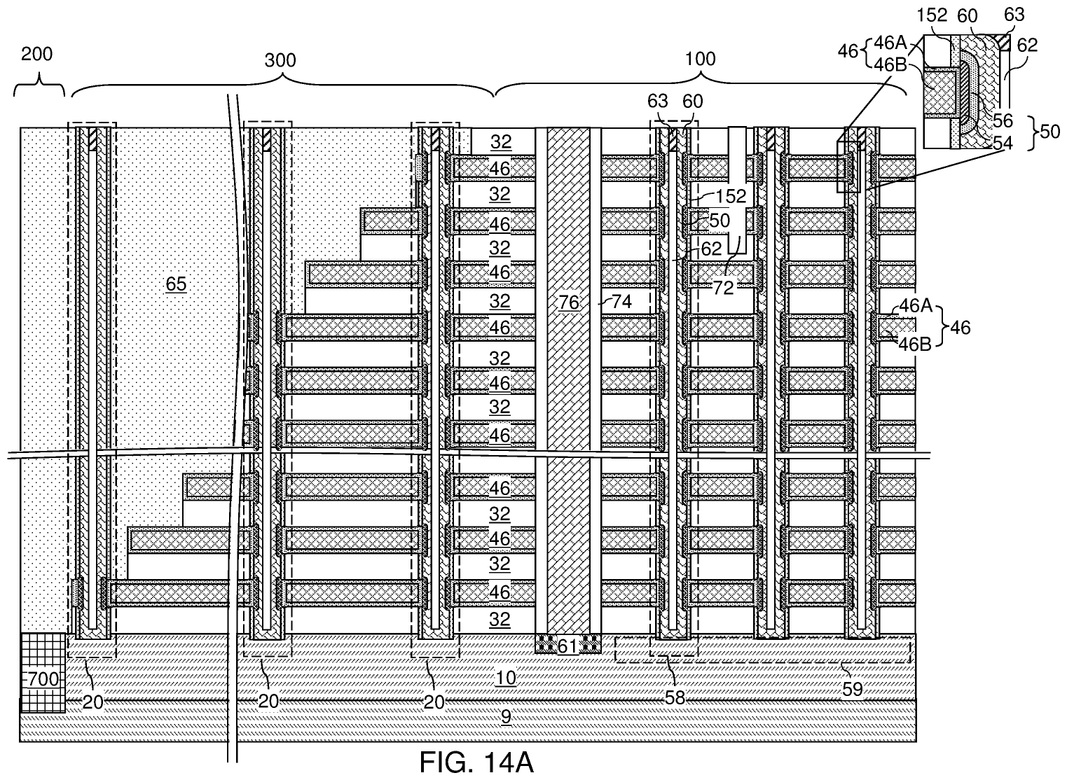

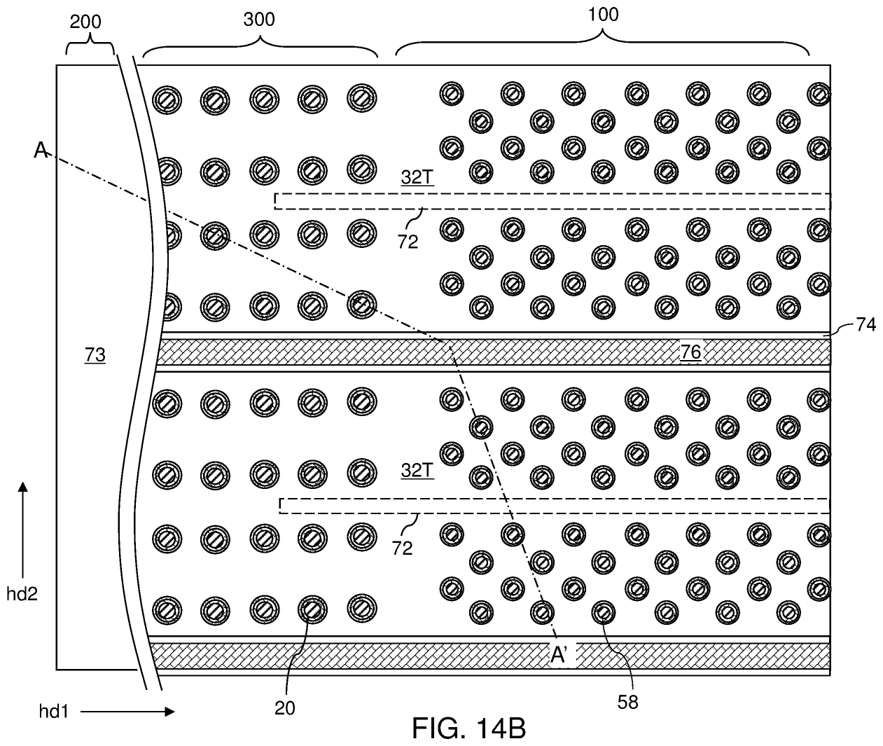

Referring to FIGS. 14A and 14B, a doped semiconductor material having a doping of the second conductivity type can be deposited within each recessed region above the dielectric cores 62. The deposited semiconductor material can have a doping of a second conductivity type that is the opposite of the first conductivity type. For example, if the first conductivity type is p-type, the second conductivity type is n-type, and vice versa. The dopant concentration in the deposited semiconductor material can be in a range from 5.0×10¹⁸/cm 3 to 2.0×10²¹/cm 3, although lesser and greater dopant concentrations can also be employed. The doped semiconductor material can be, for example, doped polysilicon or amorphous silicon.

Excess portions of the deposited semiconductor material having a doping of the second conductivity type and a horizontal portion of the semiconductor channel layer 60L can be removed from above the horizontal plane including the top surface of the topmost insulating layer 32, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

The set of all material portions formed within a memory opening 49 constitutes a memory opening fill structure 58. Each memory opening fill structure 58 may comprise a vertical stack of the discrete ferroelectric material portions 54, an optional vertical stack of discrete dielectric metal oxide portions 56, a vertical stack of tubular dielectric material portions 152, a vertical semiconductor channel 60, an optional dielectric core 62, and a drain region 63. The set of all material portions formed within a support opening 19 constitutes a support pillar structure 20.

Generally, a vertical semiconductor channel 60 can be formed over each vertical stack of discrete ferroelectric material portions 54. Each memory opening fill structure 58 comprises a vertical semiconductor channel 60 and a vertical stack of discrete ferroelectric material portions 54 located at levels of the electrically conductive layers 46.

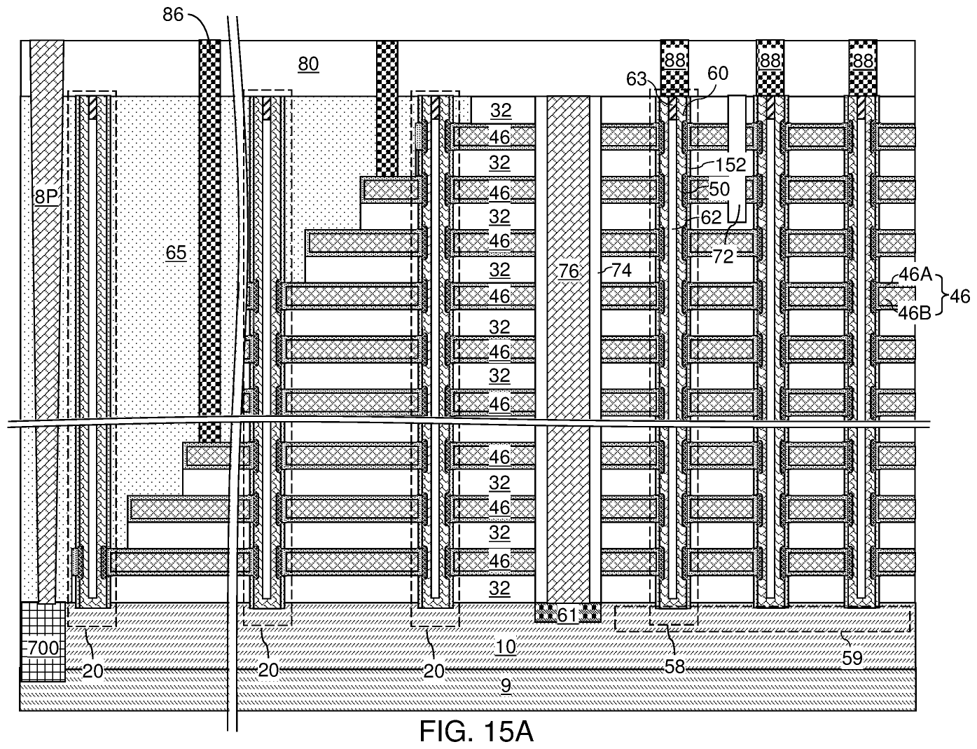

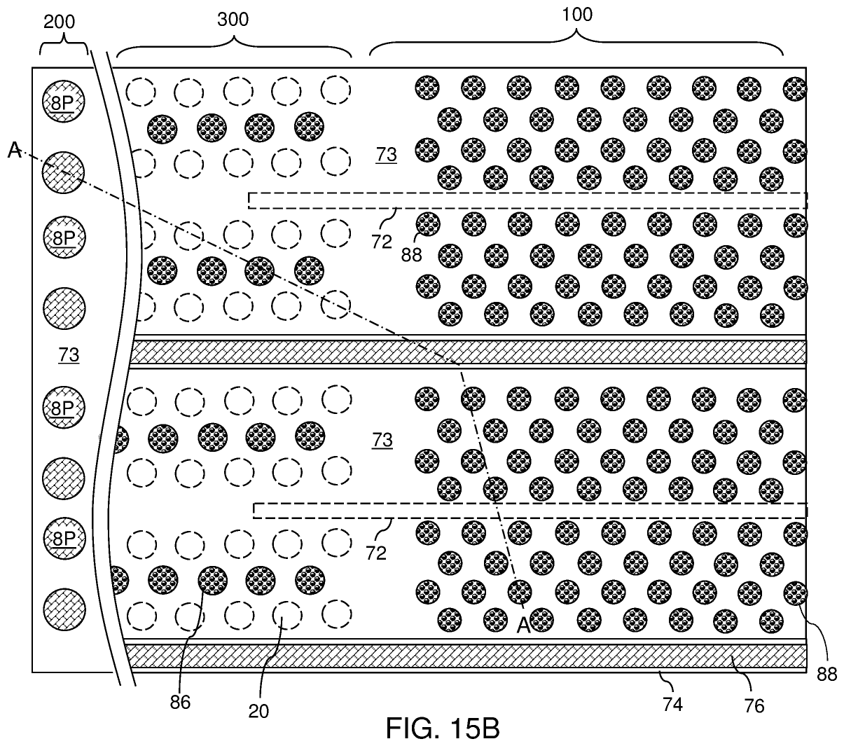

Referring to FIGS. 15A and 15B, a contact-level dielectric layer 80 can be formed over the alternating stack (32, 46) and the retro-stepped dielectric material portion 65. Drain contact via structures 88 can be formed through the contact-level dielectric layer 80 directly on a top surface of a respective drain region 63. Layer contact via structures 86 can be formed through the contact-level dielectric layer 80 and the retro-stepped dielectric material portion 65 directly on a top surface of a respective one of the electrically conductive layers 46. Peripheral contact via structures 8P can be formed through the contact-level dielectric layer 80 and the retro-stepped dielectric material portion 65 and on a respective node of the semiconductor devices 700 (if present).

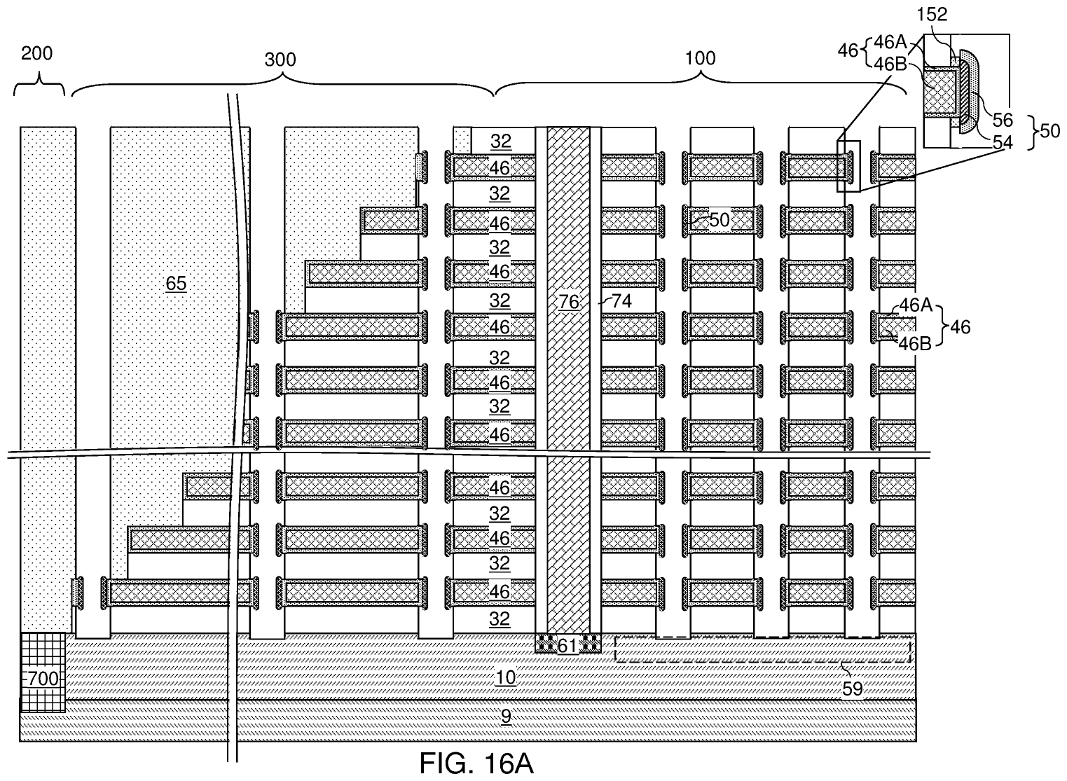

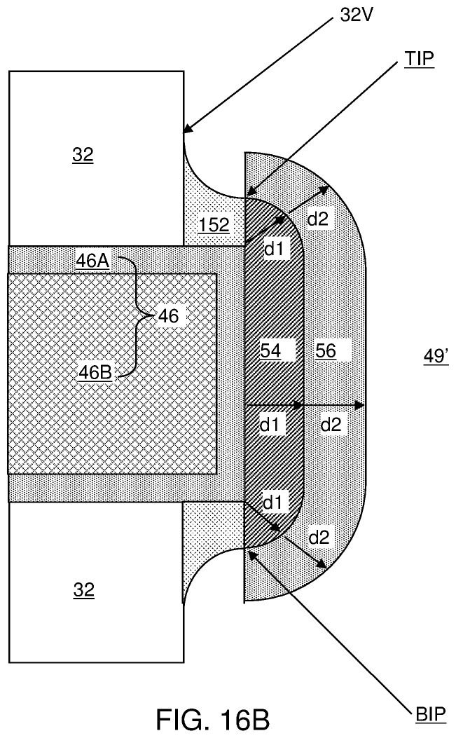

Referring to FIGS. 16A and 16B, a second exemplary structure according to a second embodiment of the present disclosure can be derived from the first exemplary structure illustrated in FIGS. 12A and 12B by removing at least a predominant portion (e.g., more than 50%) of each of the tubular dielectric material portions 152 through the memory cavities 49′ (i.e., the remaining unfilled portions of the memory openings 49). The predominant portion of each of the tubular dielectric material portions 152 may be removed by performing an isotropic recess etch process. For example, if the tubular dielectric material portions 152 comprise organosilicate glass, a wet etch process employing dilute hydrofluoric acid can be performed to etch physically exposed portions of the tubular dielectric material portions 152 from inside the memory cavities 49′ and from inside the support cavities 19′. The duration of the isotropic recess etch process may be selected such that inner sidewalls of the insulating layer 32 are at least partially physically exposed, and the electrically conductive layers 46 are not physically exposed to the memory cavities 49′ or to the support cavities 19′. In one embodiment, the recess distance of the isotropic recess etch process is less than the sum of the first distance d1 and the second distance d2. Alternatively, if the duration of the isotropic etch is extended, then the entire tubular dielectric material portions 152 may be removed from inside the memory cavities 49′. In one embodiment shown in FIG. 12B, the discrete ferroelectric material portions 54 protrude inward into the memory opening 49 relative to vertical (e.g., cylindrical) sidewalls 32V of the insulating layers 32.

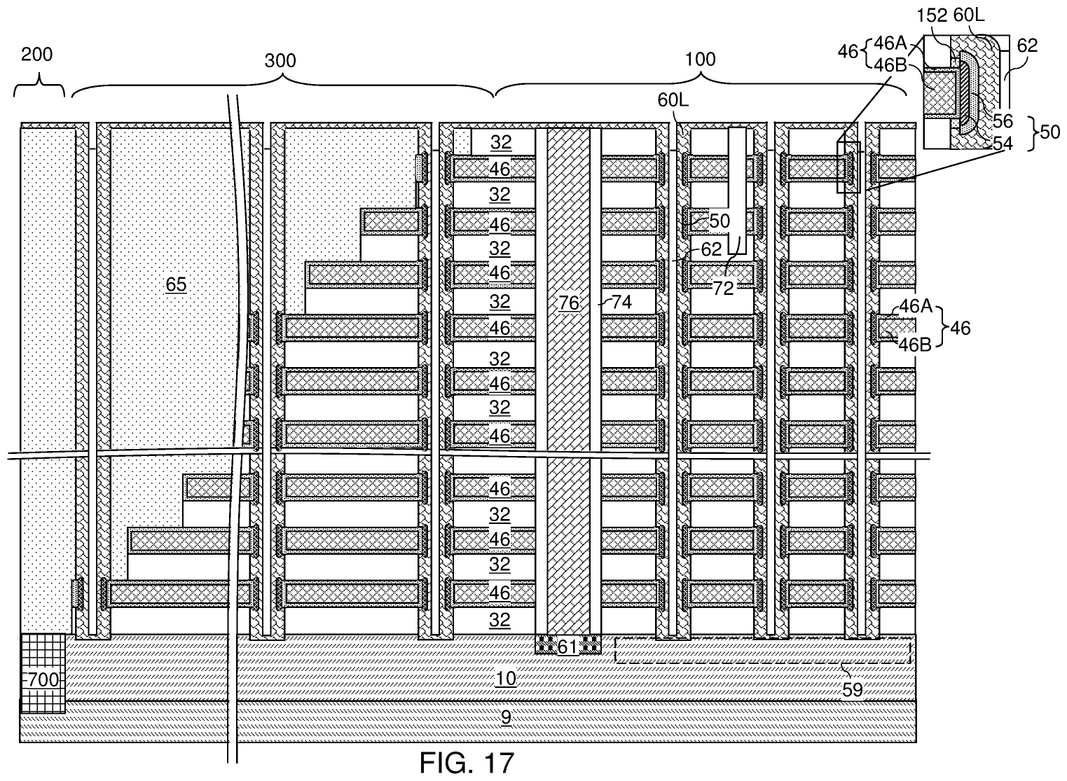

Referring to FIG. 17, the processing steps described with reference to FIG. 13 may be performed to form a semiconductor channel layer 60L and dielectric cores 62.

Referring to FIG. 18, the processing steps described with reference to FIGS. 14A and 14B may be performed to form memory opening fill structures 58 and support pillar structures 20.

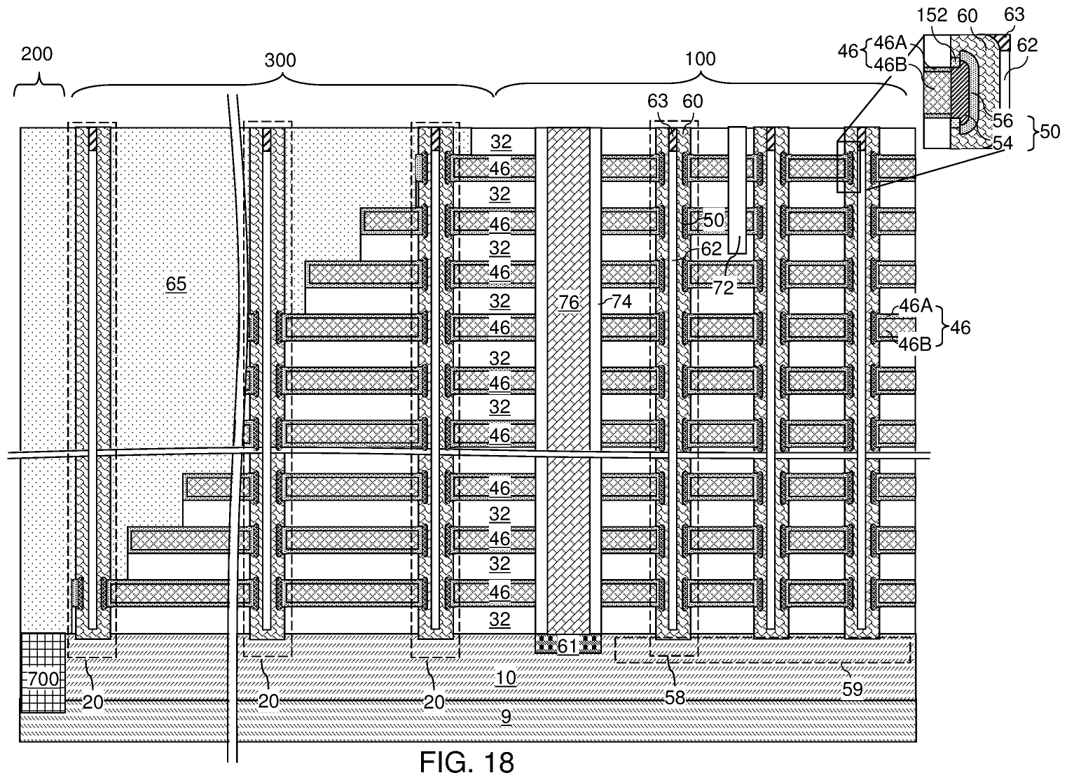

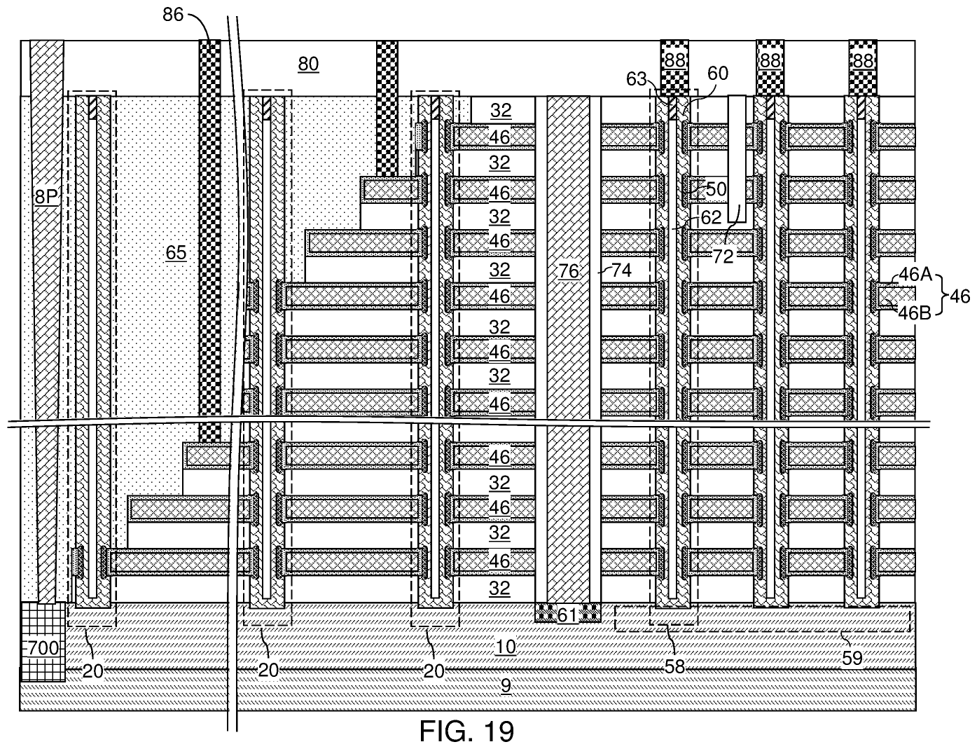

Referring to FIG. 19, the processing steps described with reference to FIGS. 15A and 15B may be performed to form a contact-level dielectric layer 80 and various contact via structures (88, 86, 8P).

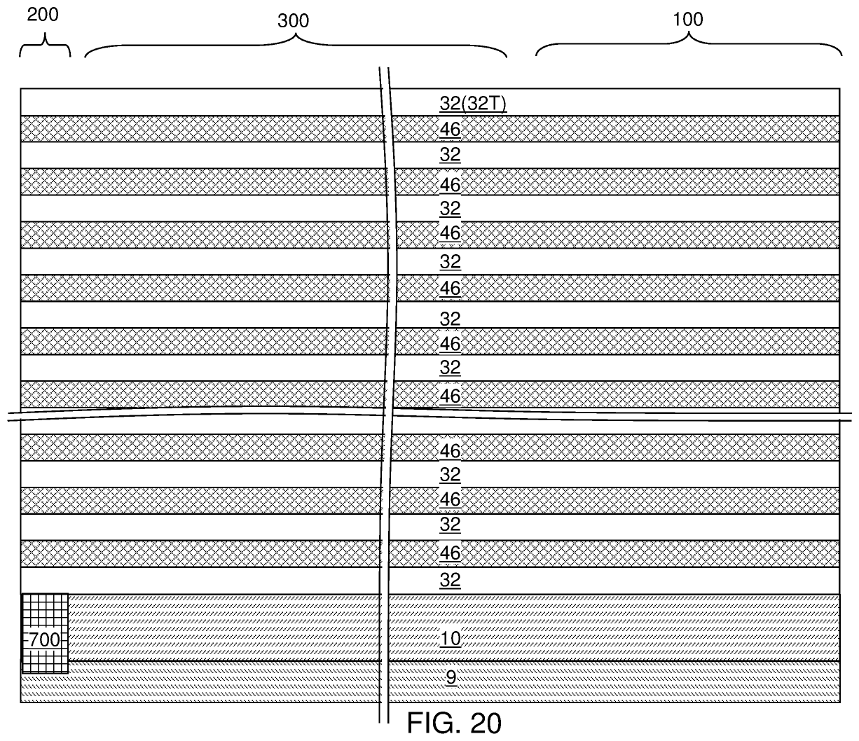

Referring to FIG. 20, a third exemplary structure according to a third embodiment of the present disclosure can be derived from the first exemplary structure illustrated in FIG. 2 by forming electrically conductive layers 46 in lieu of sacrificial material layers 42. Thus, an alternating stack of insulating layers 32 and electrically conductive layers 46 can be formed over the substrate (9, 10) and the optional semiconductor devices 700.

The electrically conductive layers 46 comprise an electrically conductive material, such as a metal. For example, the electrically conductive layers 46 may comprise, and/or may consist essentially of, a metal such as tungsten, ruthenium, molybdenum, tantalum, titanium, cobalt, etc. For example, molybdenum electrically conductive layers 46 may have hydrophilic surfaces. The thicknesses of the insulating layers 32 and the electrically conductive layers 46 may be in a range from 20 nm to 80 nm, although lesser and greater thicknesses may be employed for each insulating layer 32 and for each electrically conductive layer 46. The number of repetitions of the pairs of an insulating layer 32 and an electrically conductive layer 46 may be in a range from 2 to 1,024, and typically from 8 to 256, although a greater number of repetitions can also be employed. In one embodiment, each electrically conductive layer in the alternating stack (32, 46) can have a uniform thickness that is substantially invariant within each respective electrically conductive layer 46. The topmost layer among the insulating layers 32 is herein referred to as a topmost insulating layer 32T.

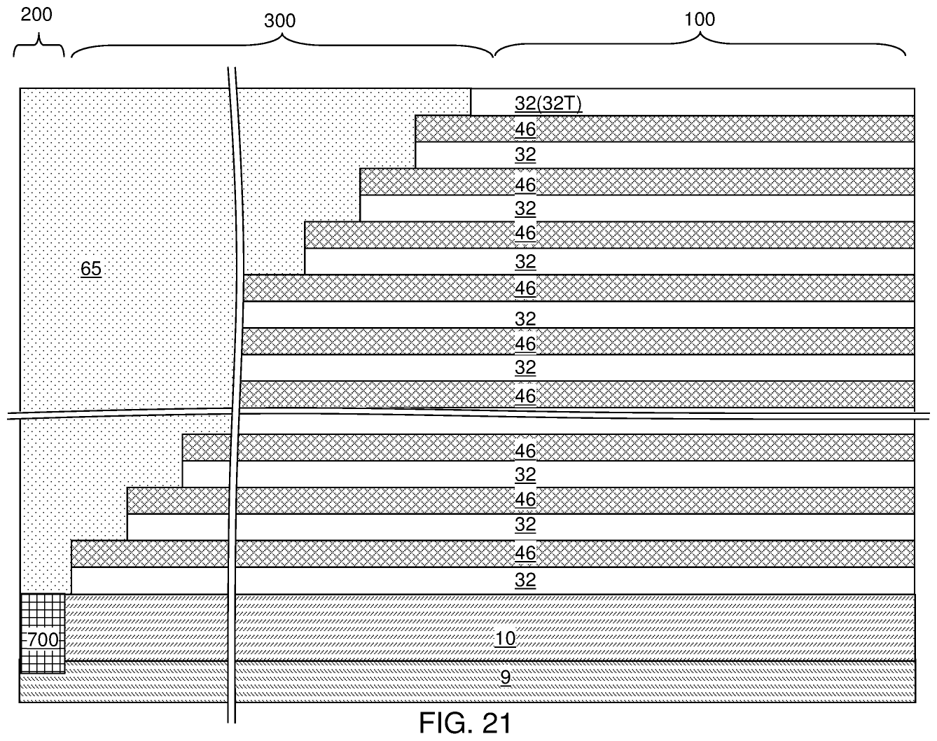

Referring to FIG. 21, the processing steps described with reference to FIG. 3 can be performed with a suitable change in the etch chemistry of the anisotropic etch processes to pattern stepped surfaces on the alternating stack (32, 46). The change in the etch chemistry of the anisotropic etch processes can be made to etch the material of the electrically conductive layers 46 in lieu of the sacrificial material layers 42. Subsequently, a retro-stepped dielectric material portion 65 can be formed over the stepped surfaces. The top surface of the retro-stepped dialectic material portion 65 may be formed within the horizontal plane including the top surface of the topmost insulating layer 32T.

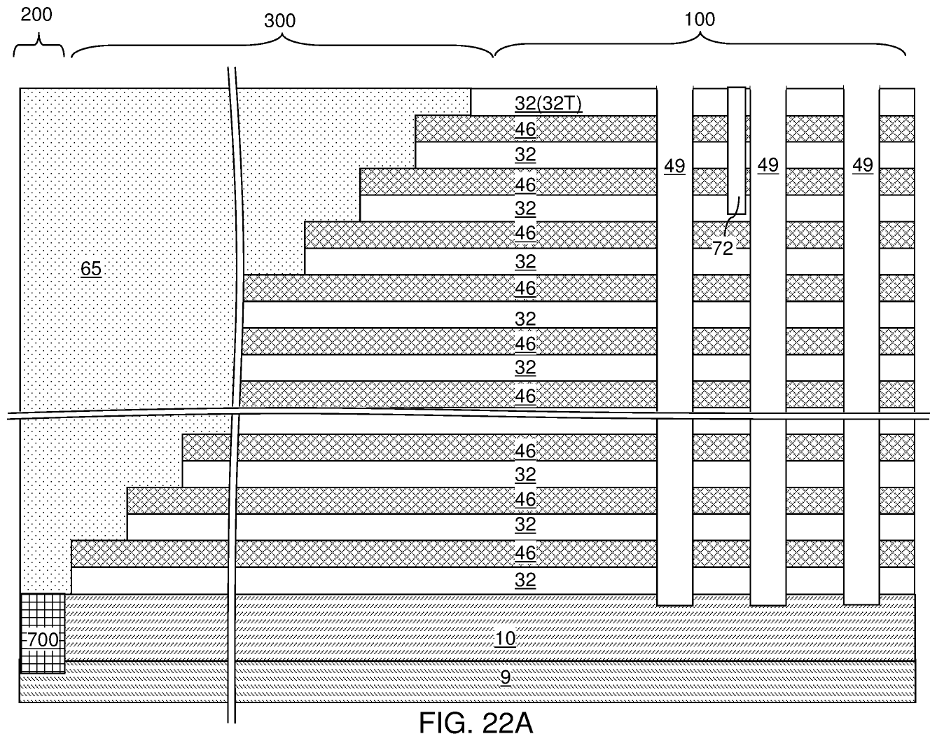

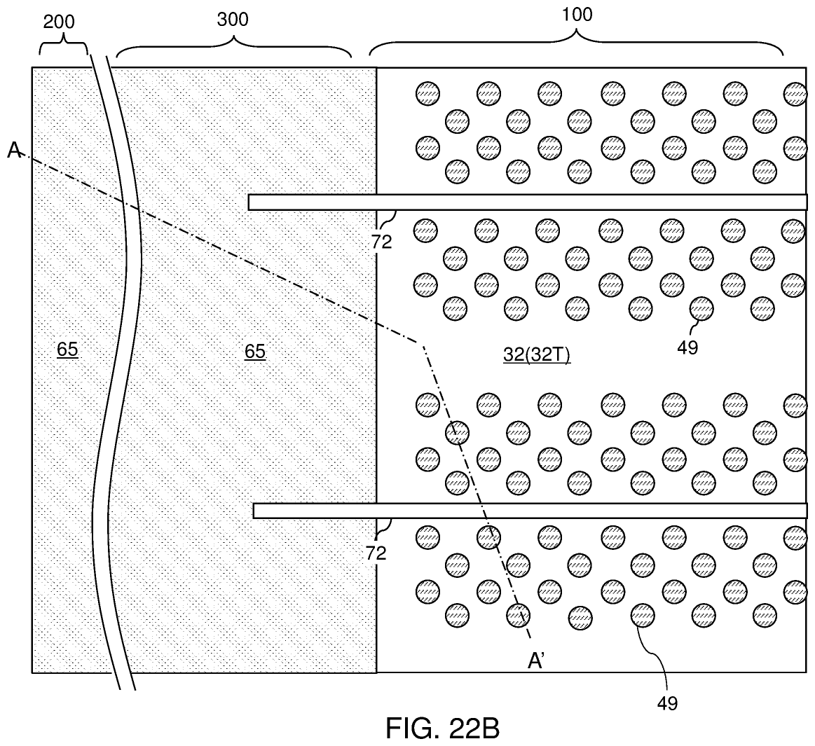

Referring to FIGS. 22A and 22B, the processing steps described with reference to FIGS. 4A and 4B can be performed with a suitable change in the etch chemistry of the anisotropic etch process to form memory openings 49. The pattern of the memory openings 49 in the third exemplary structure may be the same as the pattern of the memory openings 49 in the first exemplary structure. Support openings may be omitted in the third exemplary structure.

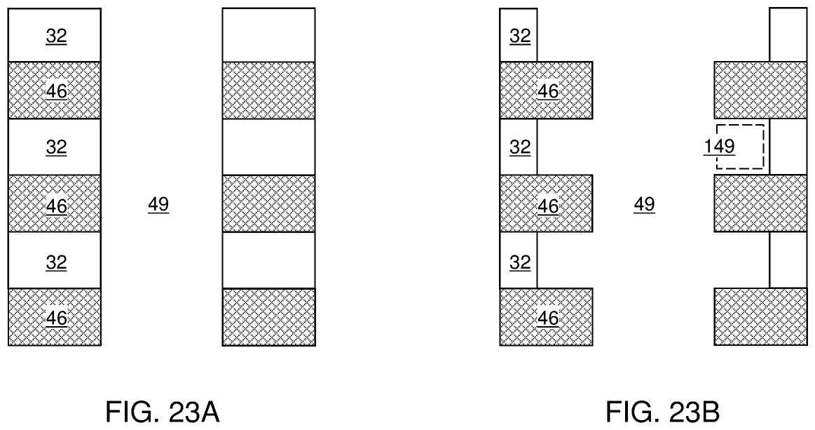

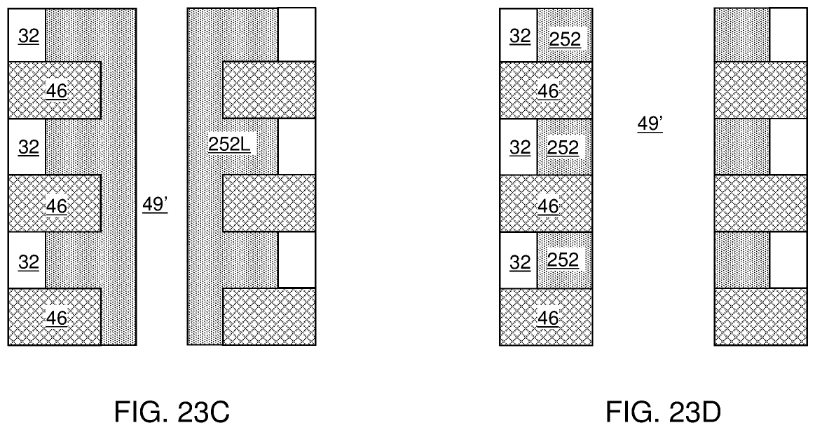

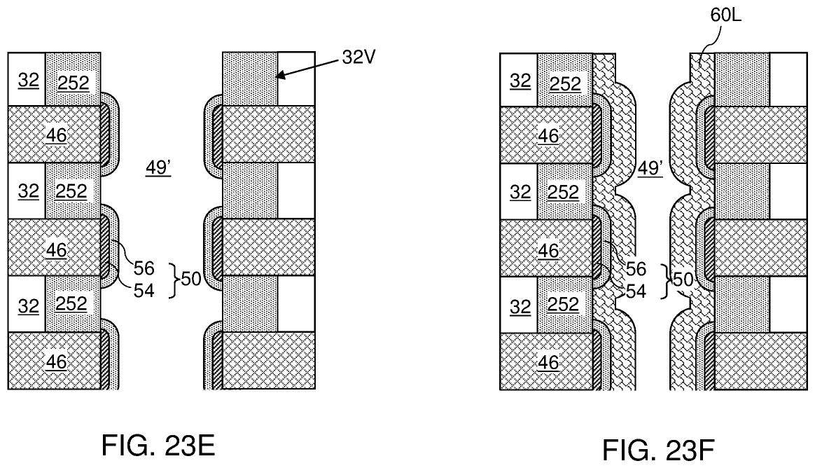

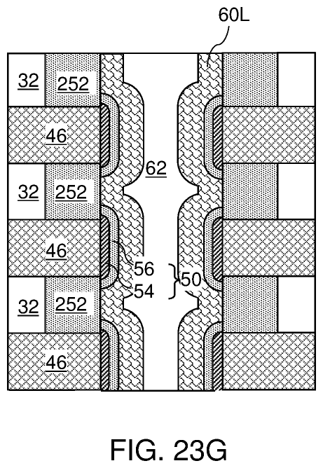

FIGS. 23A-23G are sequential vertical cross-sectional views of a region of a memory opening 49 during formation of a memory opening fill structure 58 according to the third embodiment of the present disclosure.

Referring to FIG. 23A, a portion of a memory opening 49 is illustrated after the processing steps of FIGS. 22A and 22B.

Referring to FIG. 23B, an isotropic recess etch process can be performed to isotropically recess physically exposed sidewalls of the insulating layers 32 around each memory opening 49. For example, if the insulating layers 32 comprise silicon oxide, a wet etch process employing dilute hydrofluoric acid may be performed to laterally recess the sidewalls of the insulating layers 32 selective to the electrically conductive layers 46. The lateral recess distance of the wet etch process may be greater than one half of the thickness of each insulating layer 32. In one embodiment, the lateral recess distance may be in a range from 50% to 200%, such as from 75% to 125%, of the thickness of each insulating layer 32. An annular recess cavity 149 may be formed at each level of the insulating layers 32.

Referring to FIG. 23C, a dielectric material liner layer 252L can be conformally deposited at peripheries of the memory openings 49 and over the top surface of the topmost insulating layer 32T. The dielectric material liner layer 252L comprises a dielectric material that has a hydrophobic surface, such as a methyl group-terminated surface (i.e., —CH₃ terminated surfaces) or another hydrophobic terminated surface described above. In one embodiment, the dielectric material liner layer 252L includes a dielectric material that contains a methyl group in the molecular structure. For example, the dielectric material liner layer 252L may comprise, and/or may consist essentially of, organosilicate glass comprising Si, C, 0, and H (e.g., hydrogen doped silicon oxycarbide). Generally, any organosilicate glass material having a hydrophobic surface may be employed for the dielectric material liner layer 252L. In one embodiment, the thickness of the dielectric material liner layer 252L is greater than one half of the thickness of each insulating layer 32. For example, the thickness of the dielectric material liner layer 252L may be in a range from 10 nm to 200 nm, such as from 20 nm to 100 nm, although lesser and greater thicknesses may also be employed. Each annular recess cavity 149 formed at the processing steps of FIG. 23B may be filled with a respective annular laterally-protruding portion of the dielectric material liner layer 252L.

Referring to FIG. 23D, the material of the dielectric material liner layer 252L can be etched isotropically or anisotropically. For example, an anisotropic etch process that etches the material of the dielectric material liner layer 252L selective to the material of the insulating layers 32 can be performed to remove portions of the dielectric material liner layer 252L that are not covered by an overlying portion of the insulating layers 32. Portions of the dielectric material liner layer 252L that are located within a respective one of the annular recess cavities 149 (as formed at the processing steps of FIG. 23B) remain after the anisotropic etch process. Each remaining portion of the dielectric material liner layer 252L constitutes a tubular dielectric material portion 252. A vertical stack of tubular dielectric material portions 252 can be formed at the vertical levels of the insulating layers 32 within each expanded memory opening 49. The tubular dielectric material portions 252 may comprise hydrophobic surfaces, such as —CH₃ terminated surfaces. In one embodiment, the tubular dielectric material portions 252 may comprise organosilicate glass. In one embodiment, inner sidewalls of the tubular dielectric material portions 252 may be vertically coincident with physically exposed sidewalls of the electrically conductive layers 46 around each unfilled volume of the memory opening 49, i.e., around each memory cavity 49′.

Generally, a combination of an alternating stack of insulating layers 32 and electrically conductive layers 46 having at least one opening therethrough and at least one vertical stack of tubular dielectric material portions 252 can be formed. Each of the at least one vertical stack of tubular dielectric material portions 252 can be located at a periphery of a respective opening at a level of a respective one of the insulating layers 32. In one embodiment, inner cylindrical sidewalls of a vertical stack of tubular dielectric material portions 252 around a memory cavity 49′ may be vertically coincident with cylindrical sidewalls of the electrically conductive layers 46 around the memory cavity 49′.

Referring to FIG. 23E, the processing steps described with reference to FIGS. 12A and 12B can be performed to form a vertical stack of dielectric ferroelectric material portions 54, and to optionally form a vertical stack of discrete dielectric metal oxide portions 56. In this case, the physically exposed surfaces of the tubular dielectric material portions 252 in the third exemplary structure function in the same manner as the physically exposed surfaces of the tubular dielectric material portions 152 in the first exemplary structure. Specifically, the physically exposed surfaces of the tubular dielectric material portions 252 in the third exemplary structure suppress growth of the dielectric ferroelectric material of the dielectric ferroelectric material portions 54, and suppress growth of the dielectric metal oxide material of the discrete dielectric metal oxide portions 56. In one embodiment shown in FIG. 12B, the discrete ferroelectric material portions 54 protrude inward into the memory opening 49 relative to vertical (e.g., cylindrical) sidewalls 32V of the insulating layers 32.

Referring to FIG. 23F, the processing steps described with reference to FIG. 13 can be performed to form a semiconductor channel layer 60L.

Referring to FIGS. 23G, the processing steps described with reference to FIGS. 13, 14A, and 14B can be performed to form dielectric cores 62 and drain regions 63. A memory opening fill structure 58 can be formed within each memory opening 49.

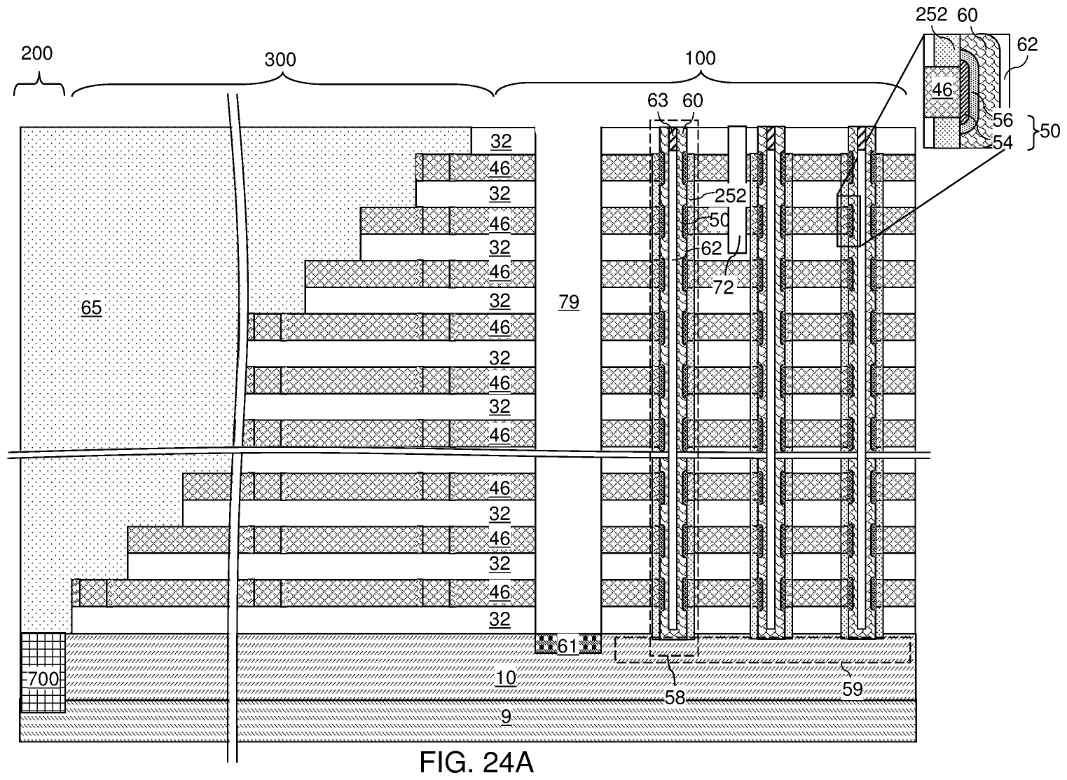

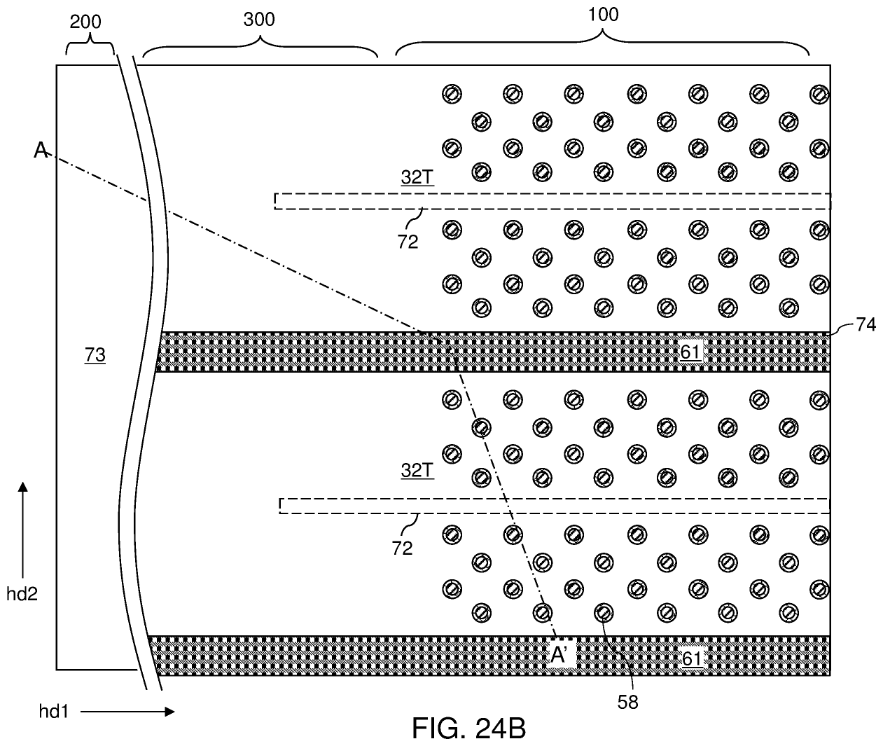

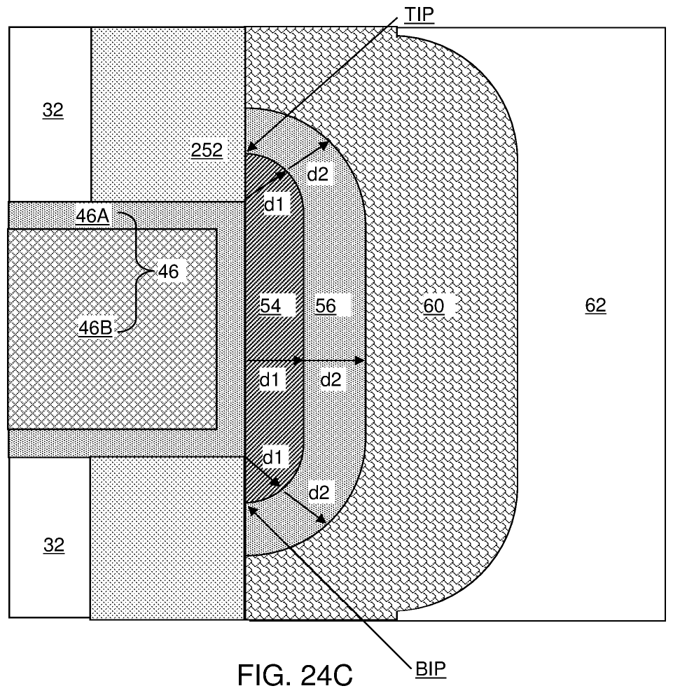

Referring to FIGS. 24A-24C, the processing steps described with reference to FIGS. 6A and 6B can be performed with a modification in the etch chemistry of the anisotropic etch process to form backside trenches 79. Formation of the sacrificial cover layer 71 may be omitted. The modification in the etch chemistry of the anisotropic etch process can be made to enable etching of the electrically conductive layers 46 in lieu of etching the sacrificial material layers 42 at the processing steps described with reference to FIGS. 6A and 6B. Source regions 61 can be formed underneath the backside trenches 79 in upper portions of the semiconductor material layer 10.

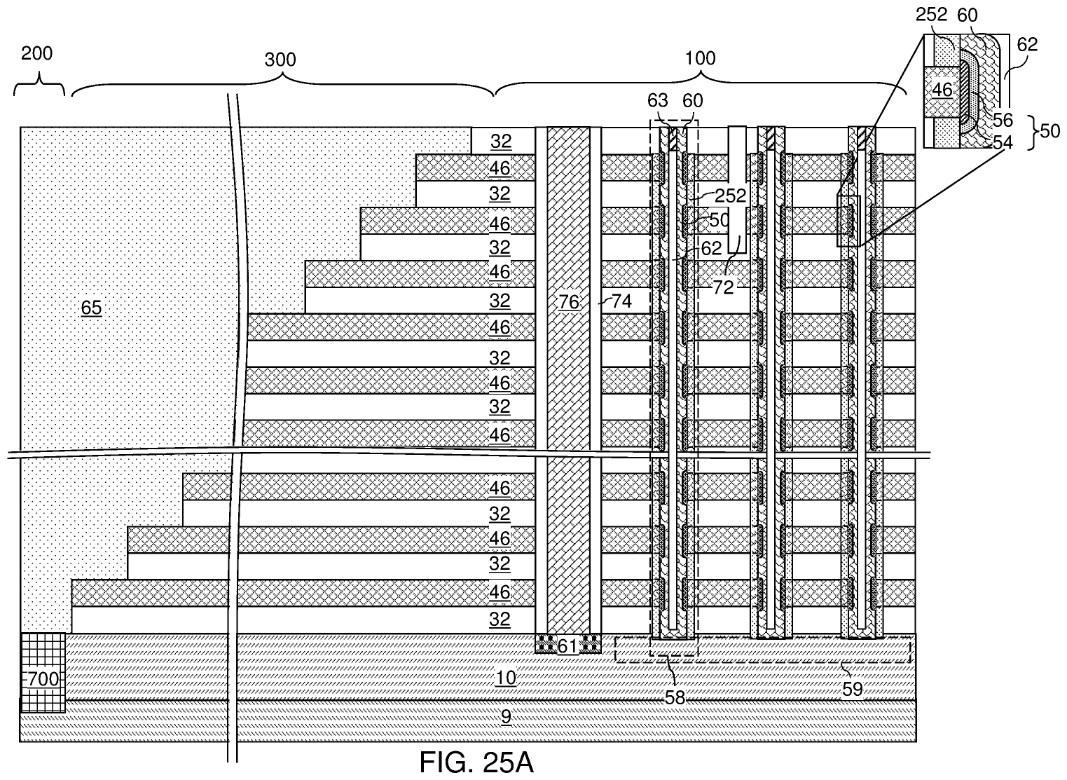

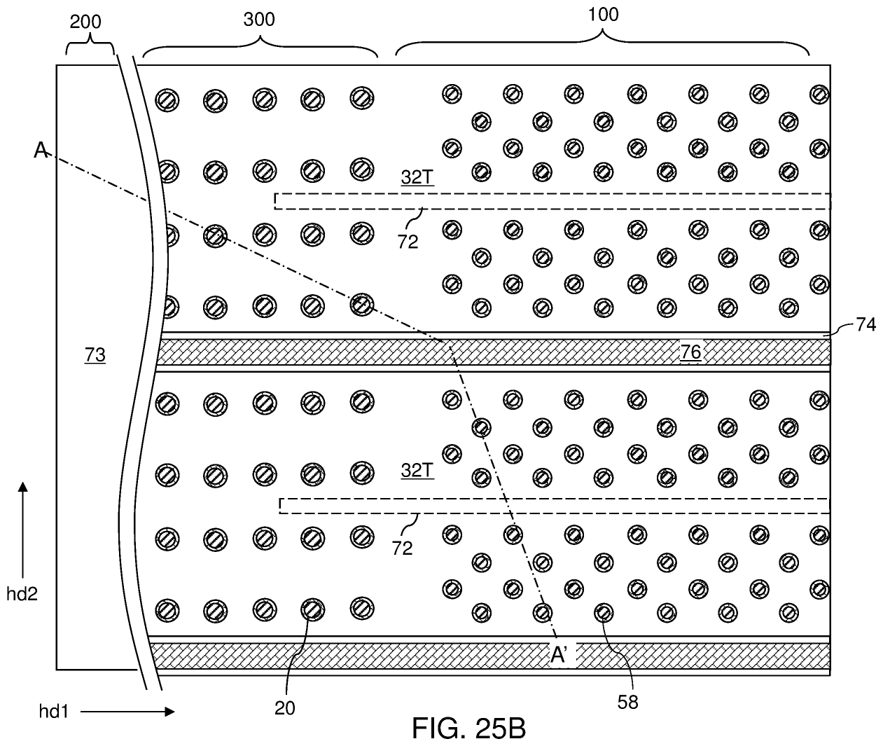

Referring to FIGS. 25A and 25B, the processing steps described with reference to FIGS. 10A and 10B can be performed to form backside trench fill structures (74, 76). The processing steps described with reference to FIGS. 10A and 10B may be modified in the third embodiment in view of the omission of the sacrificial cover layer 71 in the third exemplary structure.

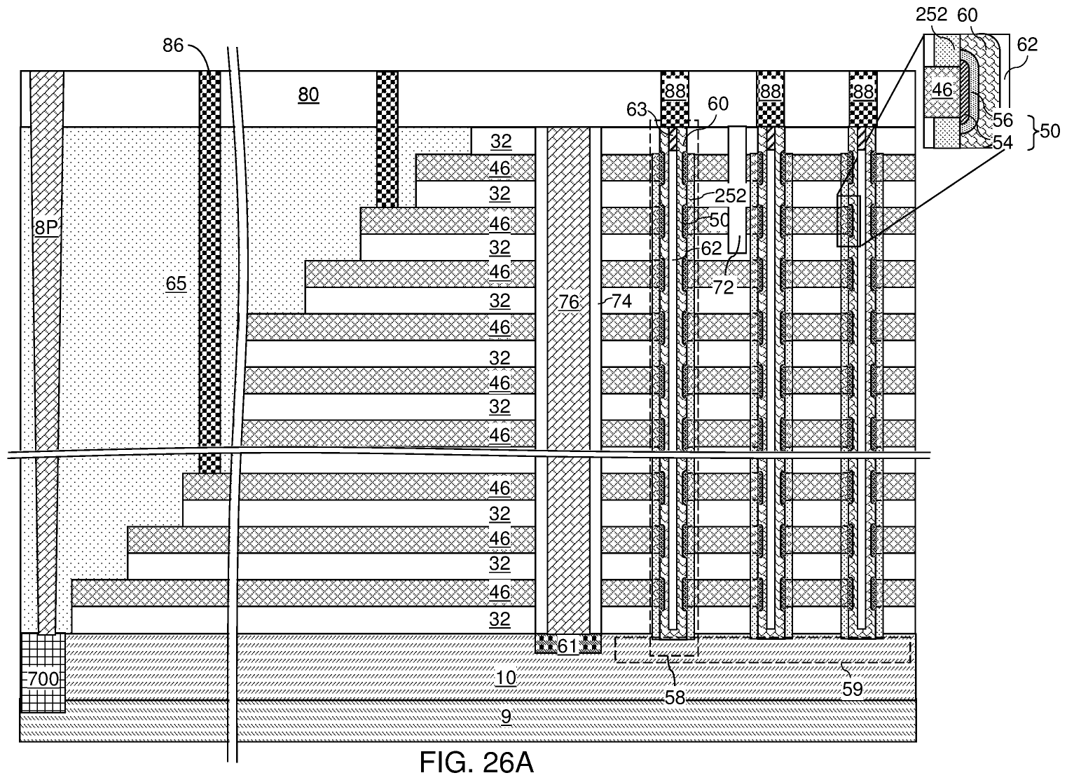

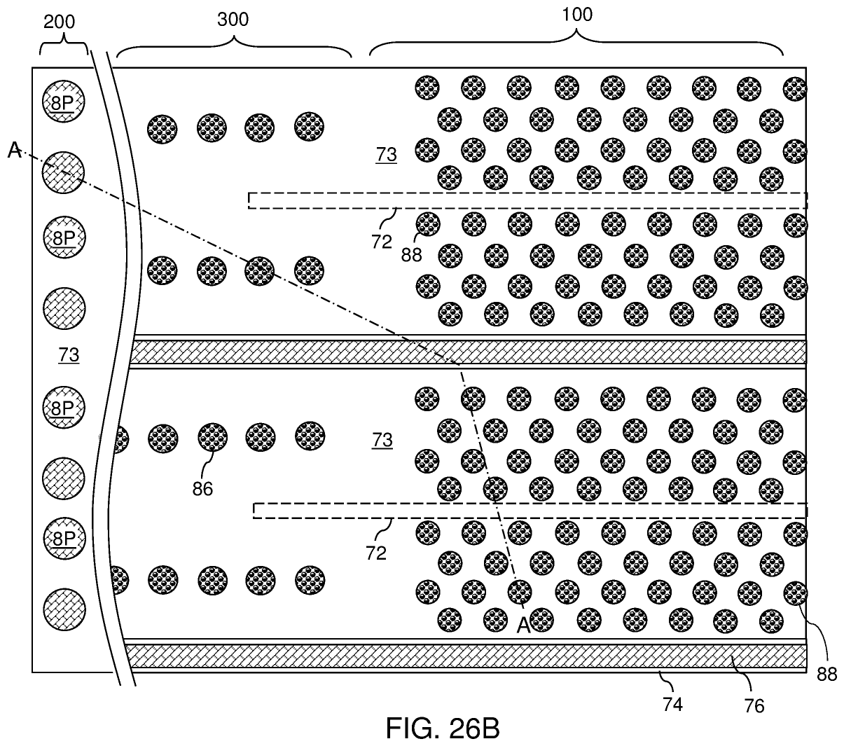

Referring to FIGS. 26A and 26B, the processing steps described with reference to FIGS. 15A and 15B may be performed to form various contact via structures (88, 86, 8P).

Referring to all drawings and according to various embodiments of the present disclosure, a semiconductor memory device comprises: an alternating stack of insulating layers 32 and electrically conductive layers 46; a memory opening 49 vertically extending through the alternating stack; and a memory opening fill structure 58 located in the memory opening 49 and comprising a vertical semiconductor channel 60 and a vertical stack of discrete ferroelectric material portions 54 located at levels of the electrically conductive layers 46. The discrete ferroelectric material portions 54 protrude inward into the memory opening 49 relative to vertical (e.g., cylindrical) sidewalls 32V of the insulating layers 32.

In one embodiment, a first discrete ferroelectric material portion 54 of the discrete ferroelectric material portions 54 comprises an outer sidewall that is in direct contact with a cylindrical sidewall of a first electrically conductive layer 46 of the electrically conductive layers 46, and an inner sidewall adjoined to the outer sidewall; and an entirety of the inner sidewall is spaced by a first distance d1 from a most proximal point within an interface between the first electrically conductive layer 46 and the outer sidewall.

In one embodiment, the inner sidewall comprises: a cylindrical surface segment; an upper convex annular surface segment that is adjoined to a top periphery of the cylindrical surface segment; and a lower convex annular surface segment that is adjoined to a bottom periphery of the cylindrical surface segment. In one embodiment, the upper convex annular surface segment has a first radius of curvature in a vertical cross-sectional view; the lower convex annular surface segment has a second radius of curvature in the vertical cross-sectional view; and the first radius of curvature and the second radius of curvature are the same as the first distance d1.

In one embodiment, an entirety of the outer sidewall is located within a cylindrical vertical plane; a top periphery of the outer sidewall coincides with a top periphery of the inner sidewall; and a bottom periphery of the outer sidewall coincides with a bottom periphery of the inner sidewall. In one embodiment, the interface between the first electrically conductive layer 46 and the outer sidewall comprises a cylindrical area having a top interface periphery TIP and a bottom interface periphery BIP; the top interface periphery TIP is spaced from the top periphery of the inner sidewall by the first distance d1; and the bottom interface periphery BIP is spaced from the bottom periphery of the inner sidewall by the first distance d1.

In one embodiment, the outer sidewall of the first discrete ferroelectric material portion 54 is located farther inward into the memory opening than the vertical sidewalls 32V of the insulating layers 32.

In one embodiment, the memory opening fill structure 58 further comprises a vertical stack of discrete dielectric metal oxide portions 56 located a respective one of the discrete ferroelectric material portions 54 within the vertical stack of discrete ferroelectric material portions 54. In one embodiment, a first discrete dielectric metal oxide portion 56 of the discrete dielectric metal oxide portions 56 is located directly on the first discrete ferroelectric material portion 54.

In one embodiment, the first discrete dielectric metal oxide portion 56 comprises a contoured inner sidewall; and each point within the contoured inner sidewall is spaced from a most proximal point within an interface between the first discrete dielectric metal oxide portion 56 and the first discrete ferroelectric material portion 54 by a second distance d2. In one embodiment, an outer sidewall of the first discrete dielectric metal oxide portion 56 comprises: a contoured annular surface segment that comprises an entirety of the interface between the first discrete dielectric metal oxide portion 56 and the first discrete ferroelectric material portion 54; an upper cylindrical surface segment adjoined to a top periphery of the contoured annular surface segment; and a lower cylindrical surface segment adjoined to a bottom periphery of the contoured annular surface segment.

In one embodiment, the memory opening fill structure 58 comprises a vertical stack of tubular dielectric material portions (152, 252) having hydrophobic surfaces that are interlaced with the vertical stack of discrete ferroelectric material portions 54 along a vertical direction; and each tubular dielectric material portion (152, 252) within the vertical stack of tubular dielectric material portions (152, 252) comprises a respective outer cylindrical sidewall that contacts a cylindrical sidewall of a respective one of the insulating layers 32.

In one embodiment, the vertical stack of tubular dielectric material portions (152, 252) comprises a material having —CH₃ terminated surfaces at interfaces with the vertical stack of discrete ferroelectric material portions 54. In one embodiment, the vertical stack of tubular dielectric material portions (152, 252) comprise organosilicate glass.

In one embodiment, the interfaces between the vertical stack of tubular dielectric material portions (152, 252) and the vertical stack of discrete ferroelectric material portions 54 comprise cylindrical surface strips having a height that is less than one half of an average vertical thickness of the insulating layers 32.

In one embodiment, the vertical stack of discrete ferroelectric material portions 54 is in direct contact with cylindrical surface segments of the insulating layers 32.

The various embodiments of the present disclosure may be employed to form self-aligned discrete ferroelectric memory elements in a three-dimensional memory device. The self-alignment method may produce thicker ferroelectric memory elements which improved ferroelectric characteristics. The discrete ferroelectric memory elements reduce interference between vertically adjacent memory cells. Furthermore, a single annealing step may be used to recrystallize the vertical semiconductor channel 60 and the ferroelectric memory elements 54.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A semiconductor memory device, comprising:
an alternating stack of insulating layers and electrically conductive layers;
a memory opening vertically extending through the alternating stack; and
a memory opening fill structure located in the memory opening and comprising a vertical semiconductor channel and a vertical stack of discrete ferroelectric material portions located at levels of the electrically conductive layers, wherein the discrete ferroelectric material portions protrude inward into the memory opening relative to vertical sidewalls of the insulating layers.

2. The semiconductor memory device of claim 1, wherein:
a first discrete ferroelectric material portion of the discrete ferroelectric material portions comprises an outer sidewall that is in direct contact with a cylindrical sidewall of a first electrically conductive layer of the electrically conductive layers, and an inner sidewall adjoined to the outer sidewall; and
an entirety of the inner sidewall is spaced by a first distance from a most proximal point within an interface between the first electrically conductive layer and the outer sidewall.

3. The semiconductor memory device of claim 2, wherein the inner sidewall comprises:
a cylindrical surface segment;
an upper convex annular surface segment that is adjoined to a top periphery of the cylindrical surface segment; and
a lower convex annular surface segment that is adjoined to a bottom periphery of the cylindrical surface segment.

4. The semiconductor memory device of claim 3, wherein:
the upper convex annular surface segment has a first radius of curvature in a vertical cross-sectional view;
the lower convex annular surface segment has a second radius of curvature in the vertical cross-sectional view; and
the first radius of curvature and the second radius of curvature are the same as the first distance.

5. The semiconductor memory device of claim 3, wherein:
an entirety of the outer sidewall is located within a cylindrical vertical plane;
a top periphery of the outer sidewall coincides with a top periphery of the inner sidewall; and
a bottom periphery of the outer sidewall coincides with a bottom periphery of the inner sidewall.

6. The semiconductor memory device of claim 5, wherein:
the interface between the first electrically conductive layer and the outer sidewall comprises a cylindrical area having a top interface periphery and a bottom interface periphery;
the top interface periphery is spaced from the top periphery of the inner sidewall by the first distance; and
the bottom interface periphery is spaced from the bottom periphery of the inner sidewall by the first distance.

7. The semiconductor memory device of claim 2, wherein the outer sidewall of the first discrete ferroelectric material portion is located farther inward into the memory opening than the vertical sidewalls of the insulating layers.

8. The semiconductor memory device of claim 1, wherein the memory opening fill structure further comprises a vertical stack of discrete dielectric metal oxide portions located on a respective one of the discrete ferroelectric material portions within the vertical stack of discrete ferroelectric material portions.

9. The semiconductor memory device of claim 8, wherein:
a first discrete dielectric metal oxide portion of the discrete dielectric metal oxide portions is located directly on the first discrete ferroelectric material portion;
the first discrete dielectric metal oxide portion comprises a contoured inner sidewall;
each point within the contoured inner sidewall is spaced from a most proximal point within an interface between the first discrete dielectric metal oxide portion and the first discrete ferroelectric material portion by a second distance; and
an outer sidewall of the first discrete dielectric metal oxide portion comprises:
a contoured annular surface segment that comprises an entirety of the interface between the first discrete dielectric metal oxide portion and the first discrete ferroelectric material portion;
an upper cylindrical surface segment adjoined to a top periphery of the contoured annular surface segment; and
a lower cylindrical surface segment adjoined to a bottom periphery of the contoured annular surface segment.

10. The semiconductor memory device of claim 1, wherein:
the memory opening fill structure further comprises a vertical stack of tubular dielectric material portions having hydrophobic surfaces that are interlaced with the vertical stack of discrete ferroelectric material portions along a vertical direction; and
each tubular dielectric material portion within the vertical stack of tubular dielectric material portions comprises a respective outer cylindrical sidewall that contacts a cylindrical sidewall of a respective one of the insulating layers.

11. The semiconductor memory device of claim 10, wherein the interfaces between the vertical stack of tubular dielectric material portions and the vertical stack of discrete ferroelectric material portions comprise cylindrical surface strips having a height that is less than one half of an average vertical thickness of the insulating layers.

12. The semiconductor memory device of claim 10, wherein the vertical stack of tubular dielectric material portions comprises a material having —CH₃ terminated surfaces.

13. The semiconductor memory device of claim 12, wherein the vertical stack of tubular dielectric material portions comprise organosilicate glass.

14. The semiconductor memory device of claim 1, wherein the vertical stack of discrete ferroelectric material portions is in direct contact with cylindrical surface segments of the insulating layers.

15. A method of forming a semiconductor memory device, comprising:
forming a combination of an alternating stack of insulating layers and electrically conductive layers having an opening therethrough and a vertical stack of tubular dielectric material portions located at a periphery of the opening at a level of a respective one of the insulating layers, wherein the vertical stack of tubular dielectric material portions comprises physically exposed hydrophobic surfaces;
forming a vertical stack of discrete ferroelectric material portions by performing a selective deposition process in which a ferroelectric material selectively grows from physically exposed surfaces of the electrically conductive layers while growth of the ferroelectric material from the physically exposed hydrophobic surfaces is suppressed; and
forming a vertical semiconductor channel over the vertical stack of discrete ferroelectric material portions.

16. The method of claim 15, wherein:
the tubular dielectric material portions comprise organosilicate glass; and
the hydrophobic surfaces comprise —CH₃ terminated surfaces.

17. The method of claim 15, wherein the discrete ferroelectric material portions protrude inward into the memory opening relative to vertical sidewalls of the insulating layers.

18. The method of claim 15, further comprising:
forming an alternating stack of the insulating layers and sacrificial material layers;
forming a memory opening through the alternating stack;
forming a dielectric material liner at a periphery of the memory opening;
forming backside recesses by removing the sacrificial material layers selective to the insulating layers;
laterally expanding the backside recesses by removing portions of the dielectric material liner around the backside recesses, wherein remaining portions of the dielectric material liner comprise the vertical stack of tubular dielectric material portions; and
forming the electrically conductive layers in the backside recesses.

19. The method of claim 18, further comprising removing at least a predominant portion of each of the tubular dielectric material portions within the vertical stack of tubular dielectric material portions prior to formation of the vertical semiconductor channel.

20. The method of claim 15, wherein forming the combination of the alternating stack and the vertical stack of tubular dielectric material portions comprises:
forming the alternating stack of insulating layers and electrically conductive layers;
forming a memory opening through the alternating stack;
isotropically recessing the insulating layers selective to the electrically conductive layers around the memory opening, wherein annular recesses are formed at levels of the insulating layers; and
forming the vertical stack of tubular dielectric material portions in the annular recesses.
